(19) United States
(12) Patent Application Publication
(10) Pub. No.: US 2018/0292751 A1
(43) Pub. Date: Oct. 11, 2018

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR MANUFACTURING ELECTRONIC DEVICE

(71) Applicant: FUJIFILM Corporation, Tokyo (JP)

(72) Inventors: Daisuke ASAKAWA, Haibara-gun (JP); Akiyoshi GOTO, Haibara-gun (JP); Yasunori YONEKUTA, Haibara-gun (JP); Naoya HATAKEYAMA, Haibara-gun (JP); Michihiro SHIRAKAWA, Haibara-gun (JP); Keiyu OU, Haibara-gun (JP)

(73) Assignee: FUJIFILM Corporation, Tokyo (JP)

(21) Appl. No.: 16/007,421

(22) Filed: Jun. 13, 2018

Related U.S. Application Data
(63) Continuation of application No. PCT/JP2016/084117, filed on Nov. 17, 2016.

(30) Foreign Application Priority Data
Dec. 22, 2015 (JP) 2015-249868

(51) Int. Cl. G03F 7/038; G03F 7/16; G03F 7/20; G03F 7/38; G03F 7/32; C08F 220/16; C08F 220/28; C08F 220/36; C08F 220/38; C08F 220/34; C08F 230/08; G03F 7/039

(52) U.S. Cl. CPC G03F 7/038; C08F 2220/382; G03F 7/168; G03F 7/2006; G03F 7/2041; G03F 7/38; G03F 7/325; C08F 220/16; C08F 220/28; C08F 220/36; C08F 220/38; C08F 220/34; C08F 230/08; G03F 7/039; C08F 2220/283; G03F 7/16

(57) ABSTRACT

The present invention has an object to provide an actinic ray-sensitive or radiation-sensitive resin composition having excellent collapse performance, an actinic ray-sensitive or radiation-sensitive film formed using the composition, a pattern forming method using the composition, and a method for manufacturing an electronic device, including the pattern forming method. The actinic ray-sensitive or radiation-sensitive resin composition of the present invention is an actinic ray-sensitive or radiation-sensitive resin composition containing a resin whose solubility with respect to a developer changes by the action of an acid, in which the resin includes a repeating unit derived from a monomer having at least one of a lactone structure or an amide structure, and the dissolution parameter of the monomer is 24.0 or more.

### CROSS-REFERENCE TO RELATED APPLICATIONS

This application is a Continuation of PCT International Application No. PCT/JP2016/084117 filed on Nov. 17, 2016, which claims priority under 35 U.S.C. § 119(a) to Japanese Patent Application No. 2015-249868 filed on Dec. 22, 2015. The above application is hereby expressly incorporated by reference, in its entirety, into the present application.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for manufacturing an electronic device. More specifically, the present invention relates to a pattern forming method which is suitable for a process for manufacturing a semiconductor such as an integrated circuit (IC), a process for manufacturing a circuit board for a liquid crystal, a thermal head, or the like, and other lithographic processes of photofabrication, as well as an actinic ray-sensitive or radiation-sensitive resin composition (resist composition) used in the pattern forming method. In addition, the present invention also relates to a method for manufacturing an electronic device, including the pattern forming method.

### 2. Description of the Related Art

In processes for manufacturing a semiconductor device such as an IC in the related art, fine processing by lithography using an actinic ray-sensitive or radiation-sensitive resin composition (resist composition) has been carried out, and various pattern forming methods have been proposed.

For example, JP2015-102749A discloses an actinic ray-sensitive or radiation-sensitive resin composition containing a specific photoacid generator and a resin having a group capable of decomposing by the action of an acid to generate a polar group.

### SUMMARY OF THE INVENTION

As various electronic devices have recently been requested to have higher functions, there has been a demand for the manufacture of finer wirings. Correspondingly, there has been a demand for a resist composition which is less likely to collapse (has excellent collapse performance) even in formation of a fine pattern.

Under such a circumstance, the present inventors have prepared a resist composition with reference to Examples of JP2015-102749A, and have formed a pattern using the same, as a result, it has thus been found that the collapse performance does not necessarily satisfy the levels which have recently been required.

Therefore, the present invention has been made in consideration of the problems, and has an object to provide an actinic ray-sensitive or radiation-sensitive resin composition having excellent collapse performance, an actinic ray-sensitive or radiation-sensitive film formed using the composition, a pattern forming method using the composition, and a method for manufacturing an electronic device, including the pattern forming method.

The present inventors have conducted extensive studies on the problem, and as a result, they have found that the problem can be solved by using a resin whose solubility with respect to a developer changes by the action of an acid, and which includes a repeating unit derived from a monomer having at least one of a lactone structure or an amide structure, the monomer having a dissolution parameter of 24.0 or more.

That is, the present inventors have found that the problem can be solved by the following configuration.

(1) An actinic ray-sensitive or radiation-sensitive resin composition comprising a resin whose solubility with respect to a developer changes by the action of an acid,

in which the resin includes a repeating unit derived from a monomer having at least one of a lactone structure or an amide structure, and

the dissolution parameter of the monomer is 24.0 or more.

(2) The actinic ray-sensitive or radiation-sensitive resin composition as described in (1),

in which the resin further includes a repeating unit having an Si atom.

(3) The actinic ray-sensitive or radiation-sensitive resin composition as described in (1) or (2),

in which the dissolution parameter of the monomer is 25.0 or more.

(4) The actinic ray-sensitive or radiation-sensitive resin composition as described in any one of (1) to (3),

in which the resin further includes a repeating unit having an acid-decomposable group.

(5) An actinic ray-sensitive or radiation-sensitive film formed using the actinic ray-sensitive or radiation-sensitive resin composition as described in any one of (1) to (4).

(6) A pattern forming method comprising:

a film forming step of forming an actinic ray-sensitive or radiation-sensitive film on a support, using the actinic ray-sensitive or radiation-sensitive resin composition as described in any one of (1) to (4);

an exposing step of exposing the actinic ray-sensitive or radiation-sensitive film; and

a developing step of developing the exposed actinic ray-sensitive or radiation-sensitive film using a developer.

(7) The pattern forming method as described in (6),

in which the developer contains an organic solvent.

(8) A method for manufacturing an electronic device, comprising the pattern forming method as described in (6) or (7).

As described below, according to the present invention, it is possible to provide an actinic ray-sensitive or radiation-sensitive resin composition having excellent collapse performance, an actinic ray-sensitive or radiation-sensitive film formed using the composition, a pattern forming method using the composition, and a method for manufacturing an electronic device, including the pattern forming method.

### DESCRIPTION OF THE PREFERRED EMBODIMENTS

Hereinafter, suitable embodiments of the present invention will be described in detail.

In citations for a group and an atomic group in the present specification, in a case where the group or the atomic group is denoted without specifying whether it is substituted or unsubstituted, the group or the atomic group includes both a group and an atomic group not having a substituent, and a group and an atomic group having a substituent. For example, an “alkyl group” which is not denoted about whether it is substituted or unsubstituted encompasses not only an alkyl group not having a substituent (unsubstituted alkyl group), but also an alkyl group having a substituent (substituted alkyl group).

In the present invention, “actinic rays” or “radiation” means, for example, a bright line spectrum of a mercury lamp, far ultraviolet rays typified by an excimer laser, extreme ultraviolet rays (EUV light), X-rays, particle rays such as electron beams and ion beams, or the like. In addition, in the present invention, “light” means actinic rays or radiation.

Furthermore, “exposure” in the present specification encompasses, unless otherwise specified, not only exposure by a mercury lamp, far ultraviolet rays typified by an excimer laser, X-rays, extreme ultraviolet rays (EUV light), or the like, but also lithography by particle rays such as electron beams and ion beams.

In the present specification, “(meth)acrylate” means “at least one of acrylate or methacrylate”. Further, “(meth)acrylic acid” means “at least one of acrylic acid or methacrylic acid”.

In the present specification, a numerical range expressed using “to” means a range that includes the preceding and succeeding numerical values of “to” as the lower limit value and the upper limit value, respectively.

[Actinic Ray-Sensitive or Radiation-Sensitive Resin Composition]

The actinic ray-sensitive or radiation-sensitive resin composition (hereinafter also referred to as “the composition of the present invention” or “the resist composition of the present invention”) of the present invention contains a resin whose solubility with respect to a developer changes by the action of an acid. Here, the resin includes a repeating unit derived from a monomer having at least one of a lactone structure or an amide structure. Further, the dissolution parameter of the monomer is 24.0 or more.

It is considered that in the present invention, such a resin (specific resin) including a repeating unit derived from specific monomer (having at least one of a lactone structure or an amide structure, and having a dissolution parameter of 24.0 or more) may be used.

In the formation of a pattern, using an actinic ray-sensitive or radiation-sensitive resin composition (resist composition), usually, an actinic ray-sensitive or radiation-sensitive (resist film) is formed on a support, using the resist composition, and then the formed film is subjected to exposure and development to form a pattern. Under these circumstances, from the studies of the present inventors, it has been found that the developer is penetrated into the pattern during the development, leading to the swelling of the pattern in some cases, and in such a case, the adhesiveness between the support and the pattern is reduced, and the pattern is easily collapsed. Further, it was also found that such tendency is remarkable in a case where the resist composition contains a resin including a repeating unit having an Si atom (particularly a resin having a cage type silsesquioxane structure).

The present invention is based on the finding, and by using a resin (specific resin) including a repeating unit derived from a monomer with a specific structure and a dissolution parameter, the swelling of the pattern as described above has been suppressed.

Hereinafter, the specific resin contained in the composition of the present invention will be firstly described, and then optional components (an acid generator and the like) which may be contained in the composition of the present invention will be described.

[1] Specific Resin

The specific resin contained in the composition of the present invention is a resin whose solubility with respect to a developer changes by the action of an acid, in which the resin includes a repeating unit (hereinafter also referred to as a “specific repeating unit”) derived from a monomer which has at least one of a lactone structure or an amide structure, and has a dissolution parameter of 24.0 or more (hereinafter also referred to as a “specific monomer”).

The specific resin may be a resin whose solubility with respect to a developer increases by the action of an acid or a resin whose solubility in a developer decreases by the action of an acid. Among those, the resin whose solubility in a developer decreases by the action of an acid is preferable, and the resin whose polarity increases by the action of an acid, with a solubility with respect to a developer including an organic solvent decreasing, is more preferable.

The specific resin is preferably a resin (hereinafter also referred to as an “acid-decomposable resin”) having a group (hereinafter also referred to as an “acid-decomposable group”) capable of decomposing by the action of an acid in either the main chain or the side chain of the resin or in both of the main chain and the side chain of the resin to generate a polar group (particularly an alkali-soluble group). Specific examples and suitable embodiments of the acid-decomposable group are the same as described later.

The repeating unit (specific repeating unit) derived from the specific monomer will be firstly described, and then optional repeating units (repeating units having an acid-decomposable group and the like) will be described.

[1-1] Repeating Unit Derived from Specific Monomer

The repeating unit (specific repeating unit) derived from the specific monomer is a repeating unit formed by the polymerization of the specific monomers.

<Specific Monomer>

The specific monomer is a monomer which has at least one of a lactone structure or an amide structure, and has a dissolution parameter of 24.0 or more.

(Lactone Structure and Amide Structure)

The specific monomer has at least one of a lactone structure or an amide structure. The specific monomer may have both of the lactone structure and the amide structure. The specific monomer may have a plurality of lactone structures or a plurality of amide structures.

Here, the lactone structure is a cyclic structure including —C(═O)—O— in a ring. Among those, the lactone structure is preferably the cyclic structure in which a hydroxy acid is produced by esterification between a carboxyl group and a hydroxyl group.

In addition, the amide structure is a structure including —C(═O)—N<. Among those, the amide structure is preferably a cyclic amide structure (lactam structure).

(Dissolution Parameter)

The dissolution parameter (SP value) of the specific monomer is 24.0 or more. Among the values, the dissolution parameter is preferably 25.0 or more, and more preferably 26.0 or more. The upper limit is not particularly limited, but is preferably 50.0 or less, and more preferably 40.0 or less.

In addition, in the present specification, the SP value is a Hansen dissolution parameter (the unit is (MPa)^{1/2}), and calculated by a software “HSPiP ver. 4” for calculating the Hansen dissolution parameter.

### Suitable Embodiments

The specific monomer is preferably represented by Formula (X).

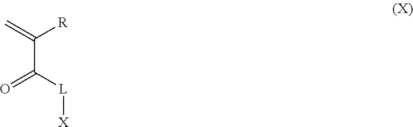

In Formula (X), R represents a hydrogen atom or an organic group.

Examples of the organic group include a fluorine atom, and an alkyl group which may have a substituent such as a hydroxyl group, and the organic group is preferably a hydrogen atom, a methyl group, a trifluoromethyl group, or a hydroxymethyl group.

In Formula (X), L represents a single bond or a divalent linking group.

Examples of the divalent organic group include a divalent aliphatic hydrocarbon group (for example, an alkylene group, preferably having 1 to 8 carbon atoms), a divalent aromatic hydrocarbon group (for example, an arylene group, preferably having 6 to 12 carbon atoms), —O—, —S—, —SO₂—, —N(R)— (R: an alkyl group), —CO—, —NH—, —COO—, —CONH—, and a group (for example, an alkyleneoxy group, an alkyleneoxycarbonyl group, and an alkylenecarbonyloxy group) formed by combination of these groups.

In Formula (X), X represents a monovalent group having at least one of a lactone structure or an amide structure. The amide structure is preferably a lactam structure.

Examples of the suitable embodiments of X include a monovalent group formed by removing any of hydrogen atoms from a compound represented by Formula (X1) or (X2).

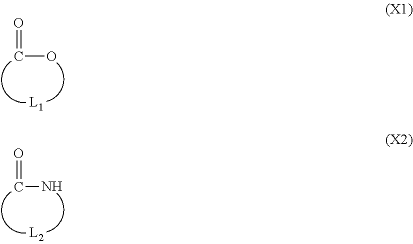

In Formulae (X1) and (X2), L₁ and L₂ each represent a divalent linking group. Specific examples of the divalent linking group are the same as L in Formula (X).

Each of L₁ and L₂ may have a substituent (for example, a substituent W which will be described later). In a case where L₁ and L₂ have two or more substituents, the substituents may be bonded to each other to form a ring, and the formed ring may further have a substituent (for example, a substituent W which will be described later). In a case where the formed rings have two or more substituents, the substituents may be bonded to each other to form a ring.

Here, the substituent W in the present specification will be described.

The substituent W in the present specification is not particularly limited, but examples thereof include a halogen atom, an alkyl group (an alkyl group having 1 to 11 carbon atoms, such as a methyl group, an ethyl group, a propyl group, a butyl group, a pentyl group, a hexyl group, a heptyl group, an octyl group, a nonyl group, a decyl group, and an undecyl group, a 2-ethylhexyl group, and the like), a cycloalkyl group (including a bicycloalkyl group, a tricycloalkyl group, and the like), an alkenyl group, a cycloalkenyl group, a 1-pentenyl group, a bicycloalkenyl group, an alkynyl group (including a 1-pentynyl group, a trimethylsilylethynyl group, a triethylsilylethynyl group, a tri-i-propylsilylethynyl group, a 2-p-propylphenylethynyl group, and the like), a cycloalkynyl group, an aryl group (including an aryl group having 6 to 20 carbon atoms, such as a phenyl group, a naphthyl group, a p-pentylphenyl group, a 3,4-dipentylphenyl group, a p-heptoxyphenyl group, a 3,4-diheptoxyphenyl group, and the like), a heterocyclic group (which may be also referred to as a hetero ring group, and includes a 2-hexylfuranyl group and the like), a cyano group, a hydroxyl group, a nitro group, an acyl group (including a hexanoyl group, a benzoyl group, and the like), an alkoxy group (including a butoxy group and the like), an aryloxy group, a silyloxy group, a heterocyclic oxy group, an acyloxy group, a carbamoyloxy group, an amino group (including an anilino group), an acylamino group, an aminocarbonylamino group (including a ureido group), alkoxy- and aryloxycarbonylamino groups, alkyl- or cycloalkyl-, and arylsulfonylamino groups, a mercapto group, alkyl- or cycloalkyl-, and arylthio groups (including a methylthio group, an octylthio group, and the like), a heterocyclic thio group, a sulfamoyl group, a sulfo group, alkyl- or cycloalkyl-, and arylsulfinyl groups, alkyl- or cycloalkyl-, and arylsulfonyl groups, alkyl- or cycloalkyl-, and aryloxycarbonyl groups, a carbamoyl group, aryl- and heterocyclic azo groups, an imido group, a phosphino group, a phosphinyl group, a phosphinyloxy group, a phosphinylamino group, a phosphono group, a silyl group, a hydrazino group, a formyl group (—CHO), a formyloxy group (—O—CHO), and other known substituents. Further, these substituents may further have the substituents.

A ratio (NO_{LX}/C_{LX}) of a total NO_{LX} of the number NO_{L} of nitrogen atoms and oxygen atoms included in L in Formula (X) and the number NO_{X} of nitrogen atoms and oxygen atoms included in X in Formula (X) to a total C_{LX} of the number C_{L} of carbon atoms included in L in Formula (X) and the number C_{X} of carbon atoms included in X in Formula (X) is preferably 0.60 to 2.00, and more preferably 0.80 to 1.50.

Furthermore, C_{LX} is preferably 2 to 20, and more preferably 3 to 10.

In addition, NO_{LX} is preferably 4 to 30, and more preferably 5 to 15.

Furthermore, the monomer represented by Formula (X) becomes a repeating unit represented by Formula (Xa) after polymerization. That is, the repeating unit represented by Formula (Xa) is a repeating unit derived from the monomer represented by Formula (X), and the monomer represented by Formula (X) is a monomer corresponding to a repeating unit represented by Formula (Xa).

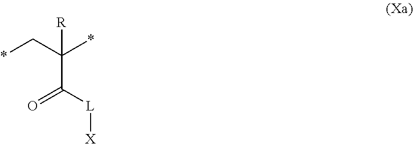

Specific examples of the specific monomer are set forth below, but are not limited thereto.

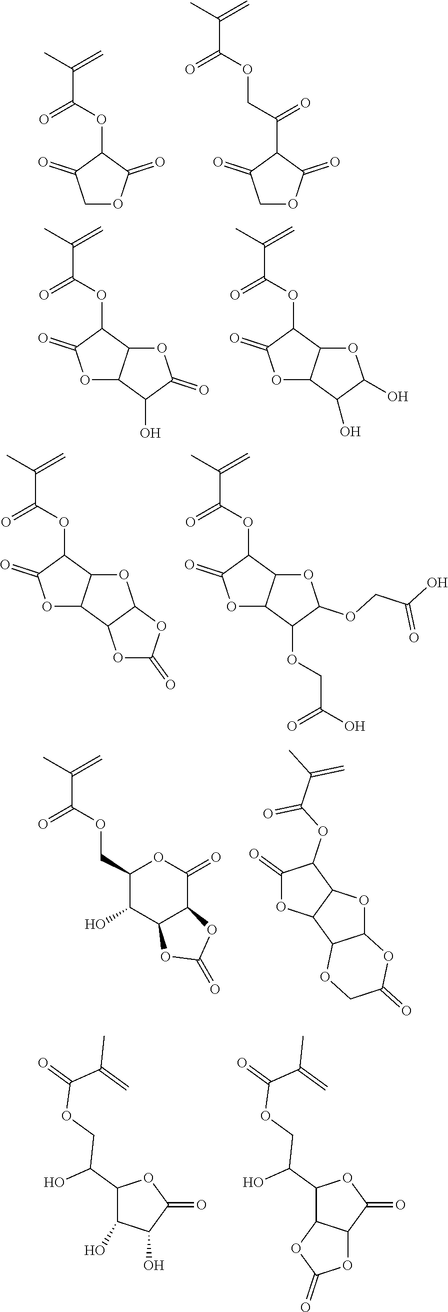

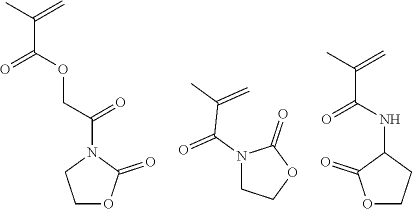

The content of the specific repeating unit with respect to all the repeating units of the specific resin is not particularly limited, but is preferably 6% to 70% by mole, more preferably 10% to 50% by mole, and still more preferably 20% to 40% by mole.

The specific repeating unit included in the specific resin may be used singly or in combination of two or more kinds thereof.

[1-2] Optional Repeating Units

<Repeating Unit Having Acid-Decomposable Group>

It is preferable that the specific resin further includes a repeating unit having an acid-decomposable group.

Here, the acid-decomposable group refers to a group capable of decomposing by the action of an acid to generate a polar group.

The acid-decomposable group preferably has a structure in which a polar group is protected with a group (leaving group) capable of decomposing by the action of an acid to leave.

The polar group is preferably a group that is poorly soluble or insoluble in a developer including an organic solvent, and specific examples thereof include an acidic group (a group that dissociates in a 2.38%-by-mass aqueous tetramethylammonium hydroxide solution which has been used as a developer in a resist in the related art) such as a phenolic hydroxyl group, a carboxyl group, a fluorinated alcohol group (preferably a hexafluoroisopropanol group), a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, and an alcoholic hydroxyl group.

Furthermore, the alcoholic hydroxyl group refers to a hydroxyl group bonded to a hydrocarbon group, which is a hydroxyl group other than a hydroxyl group (phenolic hydroxyl group) directly bonded to an aromatic ring, from which an aliphatic alcohol (for example, a fluorinated alcohol group (a hexafluoroisopropanol group or the like)) having the α-position substituted with an electron withdrawing group such as a fluorine atom is excluded as a hydroxyl group. The alcoholic hydroxyl group is preferably a hydroxyl group having an acid dissociation constant (pKa) from 12 to 20.

Preferred examples of the polar group include a carboxyl group, a fluorinated alcohol group (preferably a hexafluoroisopropanol group), and a sulfonic acid group.

A group which is preferable as the acid-decomposable group is a group in which a hydrogen atom of the polar group is substituted with a group that leaves by the action of an acid.

Examples of the group (leaving group) that leaves by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the alkyl group as each of R₃₆ to R₃₉, R₀₁, and R₀₂, an alkyl group having 1 to 8 carbon atoms is preferable, and examples thereof include a methyl group, an ethyl group, a propyl group, an n-butyl group, a sec-butyl group, a hexyl group, and an octyl group.

A cycloalkyl group as each of R₃₆ to R₃₉, R₀₁, and R₀₂ may be a monocyclic cycloalkyl group or a polycyclic cycloalkyl group. As the monocyclic cycloalkyl group, a cycloalkyl group having 3 to 8 carbon atoms is preferable, and examples thereof include a cyclopropyl group, a cyclobutyl group, a cyclopentyl group, a cyclohexyl group, and a cyclooctyl group. As the polycyclic cycloalkyl group, a cycloalkyl group having 6 to 20 carbon atoms is preferable, and examples thereof include an adamantyl group, a norbornyl group, an isobornyl group, a camphonyl group, a dicyclopentyl group, an α-pinanyl group, a tricyclodecanyl group, a tetracyclododecyl group, and an androstanyl group. Further, at least one carbon atom in the cycloalkyl group may be substituted with heteroatoms such as an oxygen atom.

An aryl group as each of R₃₆ to R₃₉, R₀₁, and R₀₂ is preferably an aryl group having 6 to 10 carbon atoms, and examples thereof include a phenyl group, a naphthyl group, and an anthryl group.

An aralkyl group as each of R₃₆ to R₃₉, R₀₁, and R₀₂ is preferably an aralkyl group having 7 to 12 carbon atoms, and examples thereof include a benzyl group, a phenethyl group, and a naphthylmethyl group.

An alkenyl group as each of R₃₆ to R₃₉, R₀₁, and R₀₂ is preferably an alkenyl group having 2 to 8 carbon atoms, and examples thereof include a vinyl group, an allyl group, a butenyl group, and a cyclohexenyl group.

A ring formed by the bonding of R₃₆ and R₃₇ is preferably a (monocyclic or polycyclic) cycloalkyl group. As the cycloalkyl group, monocyclic cycloalkyl groups such as a cyclopentyl group and a cyclohexyl group, and polycyclic cycloalkyl groups such as a norbornyl group, a tetracyclodecanyl group, a tetracyclododecanyl group, and an adamantyl group are preferable, monocyclic cycloalkyl groups having 5 or 6 carbon atoms are more preferable, and monocyclic cycloalkyl groups having 5 carbon atoms are particularly preferable.

The acid-decomposable group is preferably a cumyl ester group, an enol ester group, an acetal group, an acetal ester group, a tertiary alkyl ester group, or the like, and more preferably a tertiary alkyl ester group.

The specific resin preferably has a repeating unit represented by General Formula (AI) as the repeating unit having an acid-decomposable group. The repeating unit represented by General Formula (AI) generates a carboxyl group as a polar group by the action of an acid, and exhibits a high interaction by a hydrogen bond in a plurality of carboxyl groups, and as a result, it can more reliably make the formed pattern be poorly soluble or insoluble in a developer (in particular, a developer including an organic solvent).

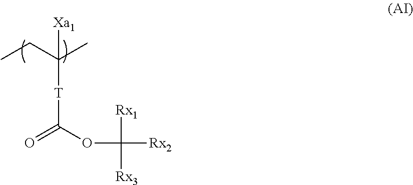

In General Formula (AI),

Xa₁ represents a hydrogen atom, an alkyl group, a cyano group, or a halogen atom.

T represents a single bond or a divalent linking group.

Rx₁ to Rx₃ each independently represent an alkyl group or a cycloalkyl group.

Two of Rx₁ to Rx₃ may be bonded to each other to form a ring structure.

T Examples of the divalent linking group of T include an alkylene group, a —COO-Rt- group, an —O-Rt- group, and a phenylene group. In the formula, Rt represents an alkylene group or a cycloalkylene group.

T is preferably a single bond or a —COO-Rt- group. Rt is preferably an alkylene group having 1 to 5 carbon atoms, and more preferably a —CH₂— group, a —(CH₂)₂— group, or a —(CH₂)₃— group. T is more preferably a single bond.

The alkyl group of Xₐ₁ may have a substituent, and examples of the substituent include a hydroxyl group and a halogen atom (preferably a fluorine atom).

The alkyl group of Xₐ₁ is preferably an alkyl group having 1 to 4 carbon atoms, and examples thereof include a methyl group, an ethyl group, a propyl group, a hydroxymethyl group, and a trifluoromethyl group, with a methyl group being preferred.

Xₐ₁ is preferably a hydrogen atom or a methyl group.

The alkyl group of each of Rx₁, Rx₂, and Rx₃ may be linear or branched, and preferred examples thereof include a methyl group, an ethyl group, an n-propyl group, an isopropyl group, an n-butyl group, an isobutyl group, and a t-butyl group. The number of carbon atoms of the alkyl group is preferably 1 to 10, and more preferably 1 to 5.

The cycloalkyl group of each of Rx₁, Rx₂, and Rx₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

As the ring structure formed by the bonding of two of Rx₁, Rx₂, and Rx₃, a monocyclic cycloalkane ring such as a cyclopentyl group and a cyclohexyl group, and a polycyclic cycloalkyl group such as a norbornyl group, a tetracyclodecanyl group, a tetracyclododecanyl group, and an adamantyl group are preferable, and a monocyclic cycloalkane ring having 5 or 6 carbon atoms is particularly preferable.

Rx₁, Rx₂, and Rx₃ are each independently preferably an alkyl group, and more preferably a linear or branched alkyl group having 1 to 4 carbon atoms.

Each of the groups may have a substituent, and examples of the substituent include an alkyl group (having 1 to 4 carbon atoms), a cycloalkyl group (having 3 to 8 carbon atoms), a halogen atom, an alkoxy group (having 1 to 4 carbon atoms), a carboxyl group, and an alkoxycarbonyl group (having 2 to 6 carbon atoms), with the groups having 8 or less carbon atoms being preferable. Among those, from the viewpoint of increasing a dissolution contrast for a developer (in particular, a developer including an organic solvent) before and after acid decomposition, the substituent is more preferably a substituent not having a heteroatom such as an oxygen atom, a nitrogen atom, and a sulfur atom (for example, a substituent other than an alkyl group substituted with a hydroxyl group is more preferable), still more preferably a group composed only of a hydrogen atom and a carbon atom, and particularly preferably a linear or branched alkyl group or a cycloalkyl group.

In General Formula (AI), Rx₁ to Rx₃ are each independently an alkyl group, and it is preferable that two of Rx₁ to Rx₃ are not bonded to each other to form a ring structure. Thus, there is tendency that an increase in the volume of a group represented by —C(Rx₁)(Rx₂)(Rx₃) as the group capable of decomposing by the action of an acid to leave can be suppressed, and a decrease in the volume of the exposed area can be suppressed in an exposing step and a post-exposure heating step that may be carried out after the exposing step.

Specific examples of the repeating unit represented by General Formula (AI) are set forth below, but the present invention is not limited to such specific examples.

In specific examples, Rx represents a hydrogen atom, CH₃, CF₃, or CH₂OH. Rxa and Rxb each independently represent an alkyl group (preferably an alkyl group having 1 to 10 carbon atoms, and more preferably an alkyl group having 1 to 5 carbon atoms). Xa₁ represents a hydrogen atom, CH₃, CF₃, or CH₂OH. Z represents a substituent, and in a case where a plurality of Z's are present, the plurality of Z's may be the same as or different from each other. p represents 0 or a positive integer. Specific examples and preferred examples of Z are the same as the specific examples and the preferred examples of the substituent which may be contained in the respective groups such as Rx₁ to Rx₃.

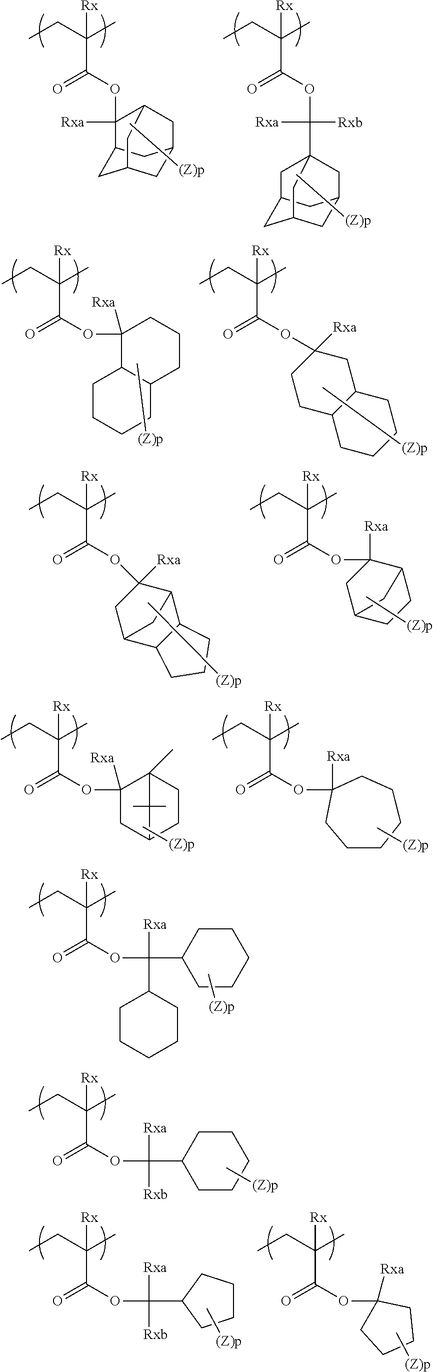

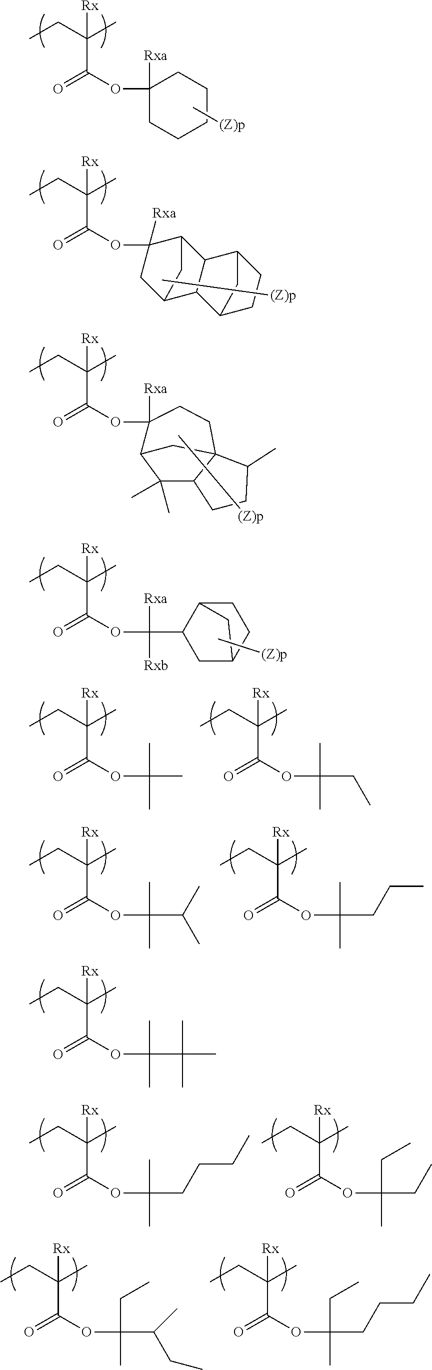

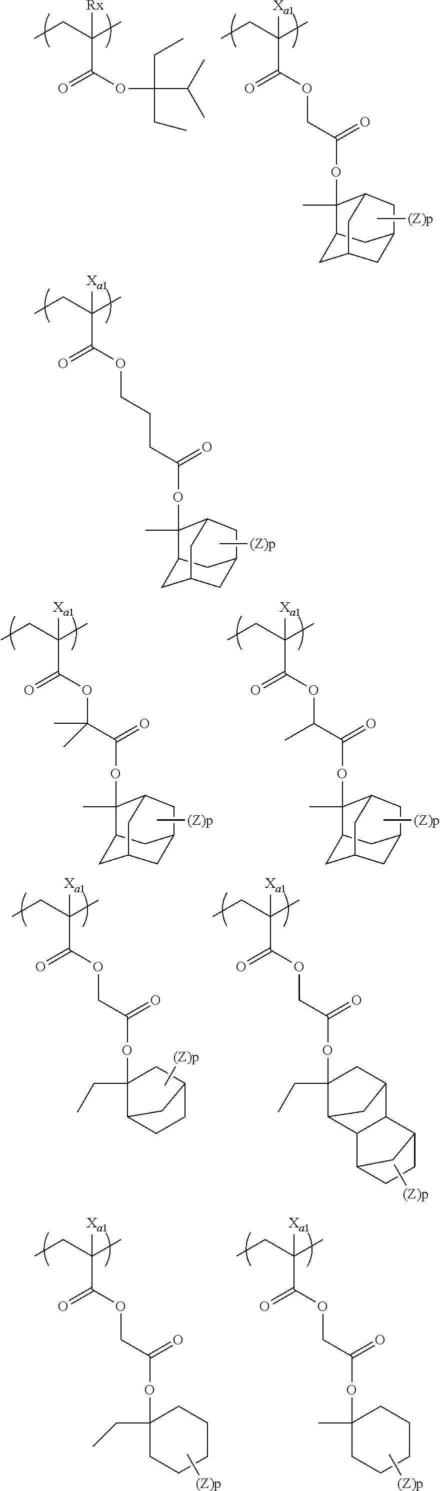

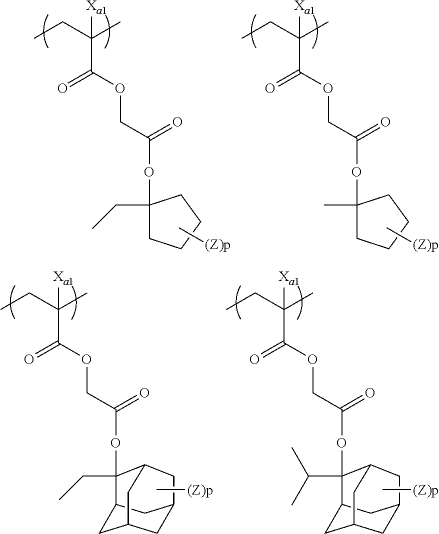

Furthermore, it is also preferable that the specific resin has the repeating unit described in paragraphs [0057] to [0071] of JP2014-202969A as the repeating unit having an acid-decomposable group.

In addition, it is also preferable that the specific resin has the repeating unit having an alcoholic hydroxyl group described in paragraphs [0072] and [0073] of JP2014-202969A as the repeating unit having an acid-decomposable group.

The content of the repeating unit having an acid-decomposable group with respect to all the repeating units of the specific resin is not particularly limited, but is preferably 20% to 90% by mole, and more preferably 40% to 80% by mole.

The repeating unit having an acid-decomposable group include in the specific resin may be used singly or in combination of two or more kinds thereof.

<Lactone Structure, Sultone Structure, or Carbonate Structure>

The specific resin may include at least one of a repeating unit having a lactone structure, a repeating unit having a sultone structure, or a repeating unit having a carbonate structure, in addition to the above-mentioned specific repeating units.

As the lactone structure or sultone structure, any structure may be used as long as it has a lactone structure or sultone structure, but the structure is preferably a 5- to 7-membered ring lactone structure or a 5- to 7-membered ring sultone structure, and more preferably a 5- to 7-membered ring lactone structure to which another ring structure is fused in the form of forming a bicyclo structure or a spiro structure or a 5- to 7-membered ring sultone structure to which another ring structure is fused in the form of forming a bicyclo structure or a spiro structure. The specific resin still more preferably has a repeating unit having a lactone structure represented by any one of General Formulae (LC1-1) to (LC1-21), or a sultone structure represented by any one of General Formulae (SL1-1) to (SL1-3). Further, the lactone structure or sultone structure may be bonded directly to the main chain. The lactone structure is preferably (LC1-1), (LC1-4), (LC1-5), (LC1-6), (LC1-13), (LC1-14), or (LC1-17), and the lactone structure is particularly preferably (LC1-4). By using such a specific lactone structure, LER and development defects are relieved.

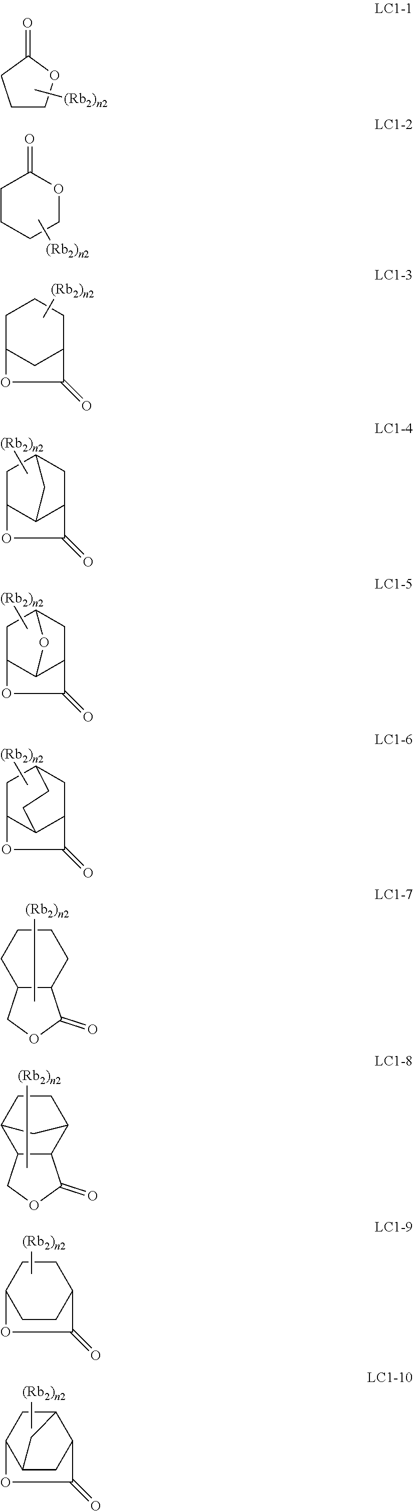

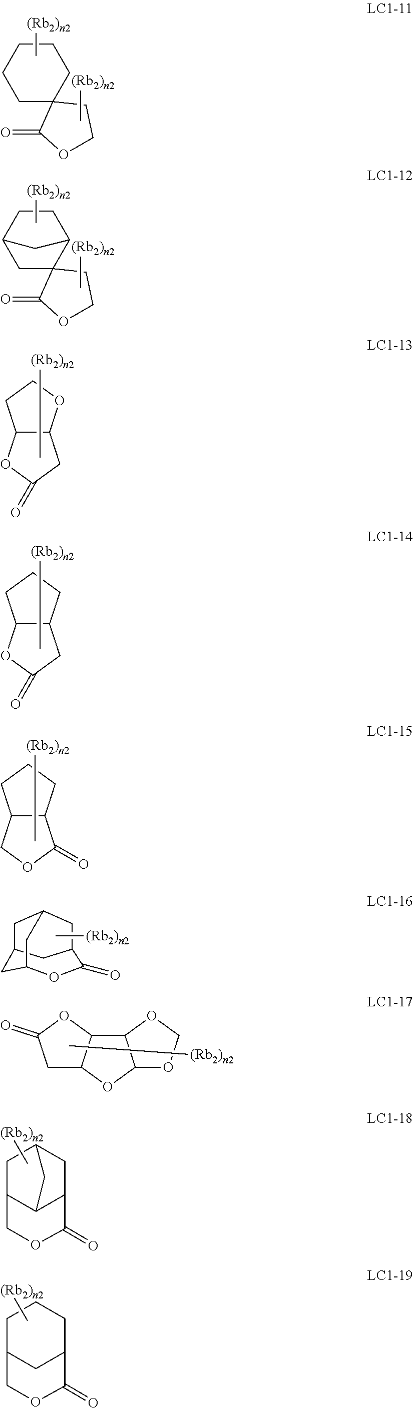

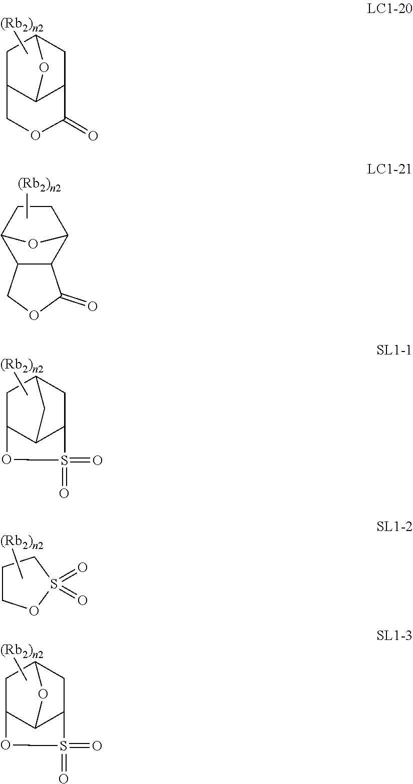

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among these, an alkyl group having 1 to 4 carbon atoms, a cyano group, and an acid-decomposable group are more preferable. n₂ represents an integer of 0 to 4. In a case where n₂ is 2 or more, the substituents (Rb₂) which are present in plural numbers may be the same as or different from each other. Further, the substituents (Rb₂) which are present in plural numbers may be bonded to each other to form a ring.

The repeating unit having a lactone structure or sultone structure usually has an optical isomer, and any optical isomer may be used. Further, one kind of optical isomer may be used singly or a plurality of optical isomers may be mixed and used. In a case of mainly using one kind of optical isomer, the optical purity (ee) thereof is preferably 90% or more, and more preferably 95% or more.

The repeating unit having a lactone structure or sultone structure is preferably a repeating unit represented by General Formula (III).

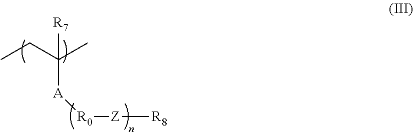

In General Formula (III),

A represents an ester bond (a group represented by —COO—) or an amide bond (a group represented by —CONH—).

In a case where R₀'s are present in plural numbers, they each independently represent an alkylene group, a cycloalkylene group, or a combination thereof.

In a case where Z's are present in plural numbers, they each independently represent a single bond, an ether bond, an ester bond, an amide bond, a urethane bond

(a group represented by

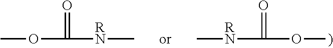

or a urea bond

(a group represented by

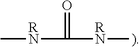

Here, R's each independently represent a hydrogen atom, an alkyl group, a cycloalkyl group, or an aryl group.

R₈ represents a monovalent organic group having a lactone structure or sultone structure.

n is the repetition number of the structure represented by —R₀—Z—, represents an integer of 0 to 5, and is preferably 0 or 1, and more preferably 0. In a case where n is 0, —R₀—Z— is not present, leading to a single bond.

R₇ represents a hydrogen atom, a halogen atom, or an alkyl group.

The alkylene group or the cycloalkylene group of R₀ may have a substituent.

Z is preferably an ether bond or an ester bond, and particularly preferably an ester bond.

The alkyl group of R₇ is preferably an alkyl group having 1 to 4 carbon atoms, more preferably a methyl group or an ethyl group, and particularly preferably a methyl group.

The alkylene group or the cycloalkylene group of R₀, and the alkyl group in R₇ may be each substituted, and examples of the substituent include a halogen atom such as a fluorine atom, a chlorine atom, and a bromine atom, a mercapto group, a hydroxyl group, an alkoxy group such as a methoxy group, an ethoxy group, an isopropoxy group, a t-butoxy group, and a benzyloxy group, and an acyloxy group such as an acetyloxy group and a propionyloxy group.

R₇ is preferably a hydrogen atom, a methyl group, a trifluoromethyl group, or a hydroxymethyl group.

The preferred chained alkylene group in R₀ is chained alkylene, preferably having 1 to 10 carbon atoms, and more preferably having 1 to 5 carbon atoms, and examples thereof include a methylene group, an ethylene group, and a propylene group. Preferred examples of the cycloalkylene group include a cycloalkylene group having 3 to 20 carbon atoms, and examples thereof include a cyclohexylene group, a cyclopentylene group, a norbornylene group, and an adamantylene group. In order to express the effects of the present invention, a chained alkylene group is more preferable, and a methylene group is particularly preferable.

The monovalent organic group having a lactone structure or sultone structure represented by R₈ is not limited as long as it has the lactone structure or sultone structure, specific examples thereof include a lactone structure or sultone structure represented by any one of General Formulae (LC1-1) to (LC1-21), and (SL1-1) to (SL1-3), and among these, the structure represented by (LC1-4) is particularly preferable. Further, n₂ in (LC1-1) to (LC1-21) is more preferably 2 or less.

Furthermore, R₈ is preferably a monovalent organic group having an unsubstituted lactone structure or sultone structure, or a monovalent organic group having a lactone structure or sultone structure having a methyl group, a cyano group, or an alkoxycarbonyl group as a substituent, and more preferably a monovalent organic group having a lactone structure having a cyano group as a substituent (cyanolactone).

In order to enhance the effects of the present invention, it is also possible to use a combination of two or more kinds of repeating units having a lactone structure or sultone structure.

In a case where the specific resin contains a repeating unit having a lactone structure or sultone structure, the content of the repeating unit having a lactone structure or sultone structure is preferably 5% to 60% by mole, more preferably 5% to 55% by mole, and still more preferably 10% to 50% by mole, with respect to all the repeating units in the specific resin.

Moreover, the specific resin may have a repeating unit having a carbonate structure (cyclic carbonic acid ester structure).

The repeating unit having a cyclic carbonic acid ester structure is preferably a repeating unit represented by General Formula (A-1).

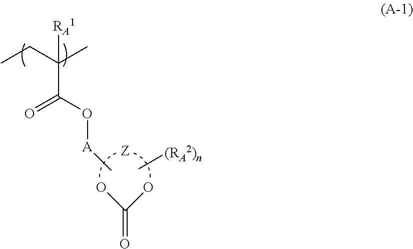

In General Formula (A-1), R_{A}¹ represents a hydrogen atom or an alkyl group.

In a case where n is 2 or more, R_{A}²'s each independently represent a substituent.

A represents a single bond or a divalent linking group.

Z represents an atomic group which forms a monocyclic or polycyclic structure together with a group represented by —O—C(═O)—O— in the formula.

n represents an integer of 0 or more.

General Formula (A-1) will be described in detail.

The alkyl group represented by R_{A}¹ may have a substituent such as a fluorine atom. R_{A}¹ is preferably a hydrogen atom, a methyl group, or a trifluoromethyl group, and more preferably a methyl group.

The substituent represented by R_{A}² is, for example, an alkyl group, a cycloalkyl group, a hydroxyl group, an alkoxy group, an amino group, or an alkoxycarbonylamino group. The substituent is preferably an alkyl group having 1 to 5 carbon atoms, and examples thereof include a linear alkyl group having 1 to 5 carbon atoms, such as a methyl group, an ethyl group, a propyl group, and a butyl group, and a branched alkyl group having 3 to 5 carbon atoms, such as an isopropyl group, an isobutyl group, and a t-butyl group. The alkyl group may have a substituent such as a hydroxyl group.

n is an integer of 0 or more, which represents the number of substituents. For example, n is preferably 0 to 4, and more preferably 0.

Examples of the divalent linking group represented by A include an alkylene group, a cycloalkylene group, an ester bond, an amide bond, an ether bond, a urethane bond, a urea bond, and combinations thereof. As the alkylene group, an alkylene group having 1 to 10 carbon atoms is preferable, an alkylene group having 1 to 5 carbon atoms is more preferable, and examples thereof include a methylene group, an ethylene group, and a propylene group.

In one embodiment of the present invention, A is preferably a single bond or an alkylene group.

Examples of a monocycle including —O—C(═O)—O—, which is represented by Z, include a 5- to 7-membered ring having n_{A} of 2 to 4, in the cyclic carbonic acid ester represented by the following General Formula (a), and the monocycle is preferably a 5-membered ring or a 6-membered ring (n_{A}=² or 3), and more preferably a 5-membered ring (n_{A}=2).

Examples of a polycycle including —O—C(═O)—O—, which is represented by Z, include a structure in which a fused ring is formed by cyclic carbonic acid ester represented by the following General Formula (a) together with one or two more other ring structures or a structure in which a spiro ring is formed. “Other ring structures” capable of forming a fused ring or a spiro ring may be an alicyclic hydrocarbon group, may be an aromatic hydrocarbon group, or may be a heterocycle.

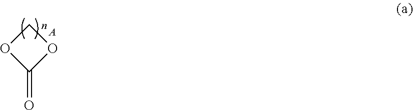

The monomer corresponding to the repeating unit represented by General Formula (A-1) can be synthesized by, for example, the method known in the related art described in Tetrahedron Letters, Vol. 27, No. 32 p. 3741 (1986), Organic Letters, Vol. 4, No. 15, p. 2561 (2002), or the like.

The specific resin may include one kind or two or more kinds of the repeating units represented by General Formula (A-1).

In the specific resin, the content of the repeating unit having a cyclic carbonic acid ester structure (preferably the repeating unit represented by General Formula (A-1)) is preferably 3% to 80% by mole, more preferably 3% to 60% by mole, particularly preferably 3% to 30% by mole, and most preferably 10% to 15% by mole, with respect to all the repeating units constituting the specific resin. By setting the content to fall within such the range, developability, low defects, low line width roughness (LWR), low post-exposure bake (PEB) temperature dependence, profiles, and the like as a resist can be improved.

The specific resin preferably has a repeating unit having a hydroxyl group or a cyano group, whereby adhesiveness to a substrate and affinity for a developer are improved. It is preferable that the repeating unit having a hydroxyl group or a cyano group is a repeating unit having an alicyclic hydrocarbon structure substituted with a hydroxyl group or a cyano group, and it is more preferable that the repeating unit does not have an acid-decomposable group. As the alicyclic hydrocarbon structure in the alicyclic hydrocarbon structure substituted with a hydroxyl group or a cyano group, an adamantyl group, a diadamantyl group, or a norbornane group is preferable. As a preferred alicyclic hydrocarbon structure substituted with a hydroxyl group or a cyano group, structures represented by the following general formulae are preferable.

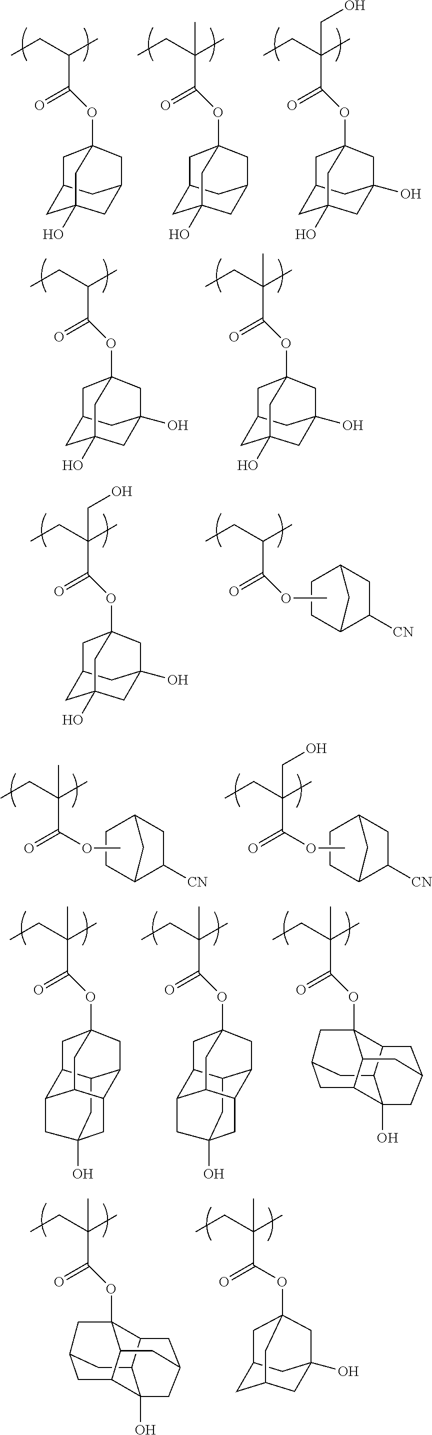

The content of the repeating unit having a hydroxyl group or a cyano group is preferably 5% to 40% by mole, more preferably 5% to 30% by mole, and still more preferably 10% to 25% by mole, with respect to all the repeating units in the specific resin.

Specific examples of the repeating unit having a hydroxyl group or a cyano group include the repeating units disclosed in paragraph 0340 of US2012/0135348A, but the present invention is not limited thereto.

The specific resin may further have a repeating unit having an alicyclic hydrocarbon structure not having a polar group (for example, the alkali-soluble group, a hydroxyl group, and a cyano group) and not exhibiting acid decomposability. Examples of such the repeating unit include a repeating unit represented by General Formula (IV).

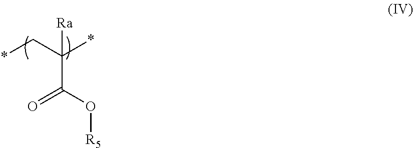

In General Formula (IV), R₅ represents a hydrocarbon group which has at least one cyclic structure and does not have a polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

The cyclic structure contained in R₅ includes a monocyclic hydrocarbon group and a polycyclic hydrocarbon group. Examples of the monocyclic hydrocarbon group include cycloalkyl groups having 3 to 12 carbon atoms, such as a cyclopentyl group, a cyclohexyl group, a cycloheptyl group, and a cyclooctyl group, a cycloalkenyl groups having 3 to 12 carbon atoms, such as a cyclohexenyl group. Preferred examples of the monocyclic hydrocarbon group include a monocyclic hydrocarbon group having 3 to 7 carbon atoms, and more preferably a cyclopentyl group and a cyclohexyl group.

Examples of the polycyclic hydrocarbon group include a ring-aggregated hydrocarbon group and a crosslinked cyclic hydrocarbon group, and examples of the ring-aggregated hydrocarbon group include a bicyclohexyl group and a perhydronaphthalenyl group. Examples of the crosslinked cyclic hydrocarbon ring include bicyclic hydrocarbon rings such as a pinane ring, a bornane ring, a norpinane ring, a norbornane ring, and a bicyclooctane ring (a bicyclo[2.2.2]octane ring, a bicyclo[3.2.1]octane ring, and the like), tricyclic hydrocarbon rings such as a homobrendane ring, an adamantane ring, a tricyclo[5.2.1.0^{2,6}]decane ring, and a tricyclo[4.3.1.1^{2,5}]undecane ring, and tetracyclic hydrocarbon rings such as a tetracyclo[4.4.0.1^{2,5}1^{7,10}]dodecane ring and a perhydro-1,4-methano-5,8-methanonaphthalene ring. Other examples of the crosslinked cyclic hydrocarbon ring include a hydrocarbon ring of a fused ring, for example, a fused ring in which a plurality of 5- to 8-membered cycloalkane rings such as a perhydronaphthalene ring (decalin), a perhydroanthracene ring, a perhydrophenanthrene ring, a perhydroacenaphthene ring, a perhydrofluorene ring, a perhydroindene ring, and a perhydrophenalene ring are fused.

Preferred examples of the crosslinked cyclic hydrocarbon ring include a norbornyl group, an adamantyl group, a bicyclooctanyl group, and a tricyclo[5,2,1,0^{2,6}]decanyl group. More preferred examples of the crosslinked cyclic hydrocarbon ring include a norbornyl group and an adamantyl group.

The specific resin may or may not contain a repeating unit having an alicyclic hydrocarbon structure not having a polar group and not exhibiting acid decomposability, but in a case where the specific resin contains the repeating unit, the content of the repeating unit is preferably 1% to 40% by mole, and more preferably 2% to 20% by mole, with respect to all the repeating units in the specific resin.

Specific examples of the repeating unit having an alicyclic hydrocarbon structure not having a polar group and not exhibiting acid decomposability include the repeating units disclosed in paragraph 0354 of US2012/0135348A, but the present invention is not limited thereto.

<Repeating Unit Having Si Atom>

It is preferable that the specific resin further includes a repeating unit having an Si atom for a reason that the etching resistance is excellent.

The repeating unit having an Si atom is not particularly limited as long as it has an Si atom. Examples thereof include a silane-based repeating unit (—SiR₂—: R₂ is an organic group), a siloxane-based repeating unit (—SiR₂—O—: R₂ is an organic group), a (meth)acrylate-based repeating unit having an Si atom, and a vinyl-based repeating unit having an Si atom.

It is preferable that the repeating unit having an Si atom does not have an acid-decomposable group.

The repeating unit having an Si atom preferably has a silsesquioxane structure. Further, the specific resin may have a silsesquioxane structure in the main chain or the side chain, but it preferably has a silsesquioxane structure in the side chain.

Examples of the silsesquioxane structure include a cage type silsesquioxane structure, a ladder type silsesquioxane structure, and a random type silsesquioxane structure. Among these, the cage type silsesquioxane structure is preferable.

Here, the cage type silsesquioxane structure is a silsesquioxane structure having a cage shape skeleton. The cage type silsesquioxane structure may be either a full cage type silsesquioxane structure or a partial cage type silsesquioxane structure, with the full cage type silsesquioxane structure being preferable.

Furthermore, the ladder type silsesquioxane structure is a silsesquioxane structure having a ladder shape skeleton.

In addition, the random type silsesquioxane structure is a silsesquioxane structure having a random skeleton.

The cage type silsesquioxane structure is preferably a siloxane structure represented by Formula (S).

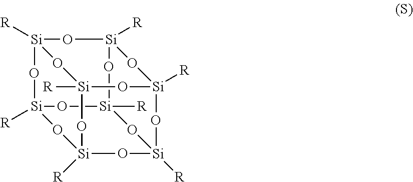

In Formula (S), R represents a monovalent organic group. R's which are present in plural numbers may be the same as or different from each other.

The organic group is not particularly limited, but specific examples thereof include a halogen atom, a hydroxyl group, a nitro group, a carboxyl group, an alkoxy group, an amino group, a mercapto group, a blocked mercapto group (for example, a mercapto group blocked (protected) with an acyl group), an acyl group, an imido group, a phosphino group, a phosphinyl group, a silyl group, a vinyl group, a hydrocarbon group which may have a heteroatom, a (meth)acryl group-containing group, and an epoxy group-containing group.

Examples of the halogen atom include a fluorine atom, a chlorine atom, a bromine atom, and an iodine atom.

Examples of the heteroatom of the hydrocarbon group which may have the heteroatom include an oxygen atom, a nitrogen atom, a sulfur atom, and a phosphorus atom.

Examples of the hydrocarbon group in the hydrocarbon group which may have the heteroatom include an aliphatic hydrocarbon group, an aromatic hydrocarbon group, and a group formed by combination thereof.

The aliphatic hydrocarbon group may be linear, branched, or cyclic. Specific examples of the aliphatic hydrocarbon group include a linear or branched alkyl group (in particular, having 1 to 30 carbon atoms), a linear or branched alkenyl group (in particular, having 2 to 30 carbon atoms), and a linear or branched alkekynyl group (in particular, having 2 to 30 carbon atoms).

Examples of the aromatic hydrocarbon group include an aromatic hydrocarbon group having 6 to 18 carbon atoms, such as a phenyl group, a tolyl group, a xylyl group, and a naphthyl group.

The repeating unit having an Si atom is preferably represented by Formula (I).

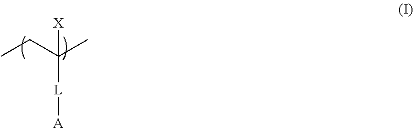

In Formula (I), L represents a single bond or a divalent linking group.

Examples of the divalent linking group include an alkylene group, a —COO-Rt- group, and an —O-Rt- group. In the formula, Rt represents an alkylene group or a cycloalkylene group.

L is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

In Formula (I), X represents a hydrogen atom or organic group.

Examples of the organic group include an alkyl group having a substituent such as a fluorine atom and a hydroxyl group, and the organic group is preferably a hydrogen atom, a methyl group, a trifluoromethyl group, or a hydroxymethyl group.

In Formula (I), A represents an Si-containing group. Among those, a group represented by Formula (a) or (b) is preferable.

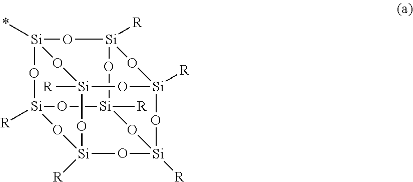

In Formula (a), R represents a monovalent organic group. R's which are present in plural numbers may be the same as or different from each other. Specific examples and suitable embodiments thereof are the same as for Formula (S). In a case where A in Formula (I) is a group represented by Formula (a), Formula (I) is represented by Formula (I-a).

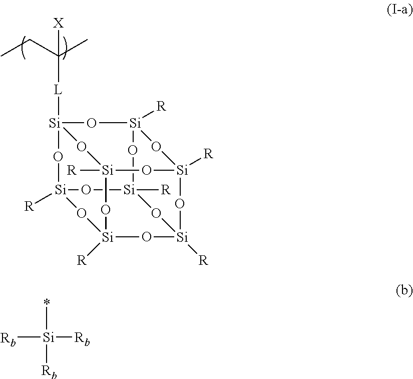

In Formula (b), R_{b} represents a hydrocarbon group which may have a heteroatom. Specific examples and suitable embodiments of the hydrocarbon group which may have a heteroatom are the same as for R in Formula (S) as described above.

The repeating unit having an Si atom included in the specific resin may be used singly or in combination of two or more kinds thereof.

The content of the repeating unit having an Si atom with respect to all the repeating units of the specific resin is not particularly limited, but is preferably 1% to 70% by mole, more preferably 3% to 50% by mole, and still more preferably 5% to 30% by mole.

The specific resin may have a repeating unit having a hydroxyl group or a cyano group. Examples of such the repeating unit include the repeating units described in paragraphs [0081] to [0084] of JP2014-098921A.

Furthermore, the specific resin may have a repeating unit having an alkali-soluble group. Examples of the alkali-soluble group include a carboxyl group, a sulfonamido group, a sulfonylimido group, a bissulfonylimido group, and an aliphatic alcohol group with the α-position being substituted with an electron withdrawing group (for example, a hexafluoroisopropanol group). Examples of the repeating unit having an alkali-soluble group include the repeating units described in paragraphs [0085] and [0086] of JP2014-098921A.

Moreover, the specific resin can have a repeating unit which has an alicyclic hydrocarbon structure not having a polar group (for example, an alkali-soluble group, a hydroxyl group, and a cyano group), and does not exhibit acid decomposability. Examples of such a repeating unit include the repeating units described in paragraphs [0114] to [0123] of JP2014-106299A.

Furthermore, the specific resin may include the repeating units described in, for example, paragraphs [0045] to [0065] of JP2009-258586A.

In addition to the repeating structural units, the specific resin can have a variety of repeating structural units for the purpose of adjusting dry etching resistance or suitability for a standard developer, adhesiveness to a substrate, and a resist profile, and in addition, resolving power, heat resistance, sensitivity, and the like, which are characteristics generally required for the resist. Examples of such repeating structural units include, but are not limited to, repeating structural units corresponding to the following monomers.

Thus, it becomes possible to perform fine adjustments to performance required for the specific resin, in particular, (1) solubility with respect to a coating solvent, (2) film forming properties (glass transition point), (3) alkali developability, (4) film reduction (selection of hydrophilic, hydrophobic, or alkali-soluble groups), (5) adhesiveness of an unexposed area to a substrate, (6) dry etching resistance, and the like.

Examples of such a monomer include a compound having one addition-polymerizable unsaturated bond selected from acrylic acid esters, methacrylic acid esters, acrylamides, methacrylamides, allyl compounds, vinyl ethers, vinyl esters, and the like.

In addition to these, an addition-polymerizable unsaturated compound that is copolymerizable with the monomers corresponding to various repeating structural units as described above may be copolymerized.

In the specific resin, the molar ratio of each repeating structural unit content is appropriately set in order to adjust dry etching resistance or suitability for a standard developer, adhesiveness to a substrate, and a resist profile of the resist, and in addition, resolving power, heat resistance, sensitivity, and the like, each of which is performance generally required for the resist.

In a case where the composition of the present invention is for ArF exposure, it is preferable that the specific resin does not substantially have an aromatic group in terms of transparency to ArF light. More specifically, the proportion of repeating units having an aromatic group in all the repeating units of the specific resin is preferably 5% by mole or less, and more preferably 3% by mole or less, and ideally 0% by mole of all the repeating units, that is, it is even more preferable that the specific resin does not have a repeating unit having an aromatic group. Further, it is preferable that the specific resin has a monocyclic or polycyclic alicyclic hydrocarbon structure.

Furthermore, it is preferable that the specific resin contains neither a fluorine atom nor a silicon atom from the viewpoint of compatibility with a hydrophobic resin (D) which will be described later.

The specific resin is preferably a resin in which all the repeating units are constituted with (meth)acrylate-based repeating units. In this case, any of a resin in which all of the repeating units are methacrylate-based repeating units, a resin in which all of the repeating units are acrylate-based repeating units, a resin in which all of the repeating units are methacrylate-based repeating units and acrylate-based repeating units can be used, but it is preferable that the acrylate-based repeating units account for 50% by mole or less of all of the repeating units.

The specific resin can be synthesized in accordance with an ordinary method (for example, radical polymerization). Examples of the general synthesis method include a bulk polymerization method in which polymerization is carried out by dissolving monomer species and an initiator in a solvent and heating the solution, a dropwise addition polymerization method in which a solution of monomer species and an initiator is added dropwise to a heating solvent for 1 to 10 hours, with the dropwise addition polymerization method being preferable. Here, as the monomer species, at least the monomer having a silicon atom, which has a turbidity of 1 ppm or less, is used. Examples of the reaction solvent include ethers such as tetrahydrofuran, 1,4-dioxane, and diisopropyl ether, ketones such as methyl ethyl ketone and methyl isobutyl ketone, ester solvents such as ethyl acetate, amide solvents such as dimethyl formamide and dimethyl acetamide, and a solvent which dissolves the composition of the present invention, such as propylene glycol monomethyl ether acetate, propylene glycol monomethyl ether, and cyclohexanone, which will be described later. It is more preferable to perform polymerization using the same solvent as the solvent used in the composition of the present invention. Thus, generation of the particles during storage can be suppressed.

It is preferable that the polymerization reaction is carried out in an inert gas atmosphere such as nitrogen and argon. As the polymerization initiator, commercially available radical initiators (an azo-based initiator, a peroxide, or the like) are used to initiate the polymerization. As the radical initiator, an azo-based initiator is preferable, and the azo-based initiator having an ester group, a cyano group, or a carboxyl group is preferable. Preferred examples of the initiator include azobisisobutyronitrile, azobisdimethylvaleronitrile, and dimethyl 2,2′-azobis(2-methyl propionate). The initiator is added or added in portionwise, as desired, a desired polymer is recovered after the reaction is completed, the reaction mixture is poured into a solvent, and then a method such as powder or solid recovery is used. The concentration of the reactant is 5% to 50% by mass, and preferably 10% to 30% by mass. The reaction temperature is normally 10° C. to 150° C., preferably 30° C. to 120° C., and more preferably 60° C. to 100° C.

The weight-average molecular weight of the specific resin is preferably 1,000 to 200,000, more preferably 2,000 to 20,000, still more preferably 3,000 to 15,000, and particularly preferably 3,000 to 11,000. By setting the weight-average molecular weight to 1,000 to 200,000, it is possible to prevent the deterioration of heat resistance or dry etching resistance, and also prevent the deterioration of film forming properties due to deteriorated developability or increased viscosity.

The dispersity (molecular weight distribution) is usually 1.0 to 3.0, and the dispersity in the range of preferably 1.0 to 2.6, more preferably 1.0 to 2.0, and particularly preferably 1.1 to 2.0 is used. As the molecular weight distribution is smaller, the resolution and the resist shape are better, the side wall of the resist pattern is smoother, and the roughness is better.

Furthermore, in the present specification, the weight-average molecular weight (Mw) and the dispersity are values in terms of standard polystyrene, determined by gel permeation chromatography (GPC) under the following conditions.
Type of columns: TSK gel Multipore HXL-M (manufactured by Tosoh Corporation, 7.8 mmID×30.0 cm)
Developing solvent: Tetrahydrofuran (THF)
Column temperature: 40° C.
Flow rate: 1 ml/min
Injection amount of sample: 10 μl
Name of device: HLC-8120 (manufactured by Tosoh Corporation)

The content of the specific resin in the total solid content of the composition of the present invention is not particularly limited, but is preferably 20% by mass or more. Among those, the content is preferably 40% by mass or more, more preferably 60% by mass or more, and still more preferably 80% by mass or more. The upper limit is not particularly limited, but is preferably 90% by mass or less.

In the present invention, the specific resin may be used singly or in combination of a plurality of kinds thereof.

The composition of the present invention may contain a resin other than the specific resin. Examples of such a resin include a resin not including a specific repeating unit, but including the above-mentioned optional repeating unit (for example, a repeating unit having an acid-decomposable group).

[2] Compound Capable of Generating Acid Upon Irradiation with Actinic Rays or Radiation

The composition of the present invention preferably contains a compound capable of generating an acid upon irradiation of actinic rays or radiation (hereinafter also referred to as an “acid generator”). The acid generator is not particularly limited, but is preferably a compound capable of generating an organic acid upon irradiation with actinic rays or radiation.

The acid generator which is appropriately selected from a photoinitiator for cationic photopolymerization, a photoinitiator for radical photopolymerization, a photodecoloring agent for dyes, a photodiscoloring agent, a known compound capable of generating an acid upon irradiation with actinic rays or radiation, which is used for a microresist or the like, and a mixture thereof, can be used. Examples thereof include the compounds described in paragraphs [0039] to [0103] of JP2010-61043A, the compounds described in paragraphs [0284] to [0389] of JP2013-4820A, and the like, but the present invention is not limited thereto.

Examples of the acid generator include a diazonium salt, a phosphonium salt, a sulfonium salt, an iodonium salt, imidosulfonate, oxime sulfonate, diazodisulfone, disulfone, and o-nitrobenzyl sulfonate.

Suitable examples of the acid generator contained in the composition of the present invention include a compound (specific acid generator) capable of generating an acid upon irradiation with actinic rays or radiation, represented by General Formula (3).

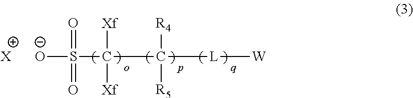

(Anion)

In General Formula (3),

Xf's each independently represent a fluorine atom or an alkyl group substituted with at least one fluorine atom.

R₄ and R₈ each independently represent a hydrogen atom, a fluorine atom, an alkyl group, or an alkyl group substituted with at least one fluorine atom, and in a case where R₄ and R₈ are present in plural numbers, they may be the same as or different from each other.

L represents a divalent linking group, and in a case where L's are present in plural numbers, they may be the same as or different from each other.

W represents an organic group including a cyclic structure.

o represents an integer of 1 to 3. p represents an integer of 0 to 10. q represents an integer of 0 to 10.

Xf represents a fluorine atom or an alkyl group substituted with at least one fluorine atom. The number of carbon atoms of the alkyl group is preferably 1 to 10, and more preferably 1 to 4. Further, the alkyl group substituted with at least one fluorine atom is preferably a perfluoroalkyl group.

Xf is preferably a fluorine atom or a perfluoroalkyl group having 1 to 4 carbon atoms. Xf is more preferably a fluorine atom or CF₃. It is particularly preferable that both Xf's are fluorine atoms.

R₄ and R₅ each independently represent a hydrogen atom, a fluorine atom, an alkyl group, or an alkyl group substituted with at least one fluorine atom, and in a case where R₄ and R₅ are each present in plural numbers, they may be the same as or different from each other. The alkyl group as each of R₄ and R₅ may have a substituent, and preferably has 1 to 4 carbon atoms. R₄ and R₅ are each preferably a hydrogen atom.

Specific examples and suitable embodiments of the alkyl group substituted with at least one fluorine atom are the same as the specific examples and suitable embodiments of Xf in General Formula (3).

L represents a divalent linking group, and in a case where L's are present in plural numbers, they may be the same as or different from each other.

Examples of the divalent linking group include —COO—(—C(═O)—O—), —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), or a divalent linking group formed by combination of these plurality of groups. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferable, and —COO—, —OCO—, —CONH—, —SO₂—, —COO-alkylene group-, or —OCO-alkylene group- is more preferable.

W represents an organic group including a cyclic structure. Among the organic groups, a cyclic organic group is preferable.

Examples of the cyclic organic group include an alicyclic group, an aryl group, and a heterocyclic group.

The alicyclic group may be monocyclic or polycyclic, and examples of the monocyclic alicyclic group include monocyclic cycloalkyl groups such as a cyclopentyl group, a cyclohexyl group, and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among these, an alicyclic group having a bulky structure having 7 or more carbon atoms, such as a norbornyl group, a tricyclodecanyl group, a tetracyclodecanyl group, a tetracyclododecanyl group, and an adamantyl group is preferable from the viewpoints of suppressing diffusivity into the film during the post-exposure bake (PEB) process and improving a mask error enhancement factor (MEEF).

The aryl group may be monocyclic or polycyclic. Examples of the aryl group include a phenyl group, a naphthyl group, a phenanthryl group, and an anthryl group. Among these, a naphthyl group showing a relatively low light absorbance at 193 nm is preferable.

The heterocyclic group may be monocyclic or polycyclic, but in a case where it is polycyclic, it is possible to suppress acid diffusion. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having an aromaticity include a tetrahydropyran ring, a lactone ring, a sultone ring, and a decahydroisoquinoline ring. As a heterocycle in the heterocyclic group, a furan ring, a thiophene ring, a pyridine ring, or a decahydroisoquinoline ring is particularly preferable. Further, examples of the lactone ring and the sultone ring include the above-mentioned lactone structures and sultone structures exemplified in the resin.

The cyclic organic group may have a substituent. Examples of the substituent include, an alkyl group (which may be linear or branched, and preferably has 1 to 12 carbon atoms), a cycloalkyl group (which may be monocyclic, polycyclic, or spiro ring, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (carbon contributing to ring formation) may be carbonyl carbon.

o represents an integer of 1 to 3. p represents an integer of 0 to 10. q represents an integer of 0 to 10.

In one embodiment, it is preferable that in General Formula (3), o is an integer of 1 to 3, p is an integer of 1 to 10, and q is 0. Xf is preferably a fluorine atom, R₄ and R₅ are preferably both hydrogen atoms, and W is preferably a polycyclic hydrocarbon group. o is more preferably 1 or 2, and still more preferably 1. p is more preferably an integer of 1 to 3, still more preferably 1 or 2, and particularly preferably 1. W is more preferably a polycyclic cycloalkyl group, and still more preferably an adamantyl group or a diadamantyl group.

(Cation)

In General Formula (3), X⁺ represents a cation.

X⁺ is not particularly limited as long as it is a cation, but suitable embodiments thereof include cations (parts other than Z⁻) in General Formula (ZI), (ZII), or (ZIII) which will be described later.

### Suitable Embodiments

Suitable specific embodiments of the acid generator include a compound represented by General Formula (ZI), (ZII), or (ZIII).

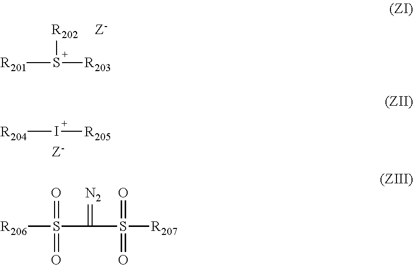

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two members out of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two members out of R₂₀₁ to R₂₀₃ include an alkylene group (for example, a butylene group and a pentylene group).

Z⁻ represents an anion in General Formula (3), and specifically represents the following anion.

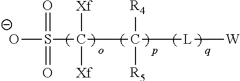

Examples of the organic group represented by each of R₂₀₁, R₂₀₂, and R₂₀₃ include groups corresponding to the compounds (ZI-1), (ZI-2), (ZI-3) and (ZI-4) which will be described later.

Incidentally, the organic group may be a compound having a plurality of structures represented by General Formula (ZI). For example, it may be a compound having a structure in which at least one of R₂₀₁, . . . , or R₂₀₃ in the compound represented by General Formula (ZI) is bonded to at least one of R₂₀₁, . . . , or R₂₀₃ of another compound represented by General Formula (ZI) through a single bond or a linking group.

More preferred examples of the component (ZI) include compounds (ZI-1), (ZI-2), (ZI-3), and (ZI-4) described below.

First, the compound (ZI-1) will be described.

The compound (ZI-1) is an arylsulfonium compound in which at least one of R₂₀₁, . . . , or R₂₀₃ in General Formula (ZI) is an aryl group, that is, a compound having arylsulfonium as a cation.

In the arylsulfonium compound, all of R₂₀₁ to R₂₀₃ may be aryl groups, or some of R₂₀₁ to R₂₀₃ may be aryl groups and the remainders may be alkyl groups or cycloalkyl groups, but all of R₂₀₁ to R₂₀₃ may be aryl groups.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium compound has two or more aryl groups, these two or more aryl groups may be the same as or different from each other.

The alkyl group or the cycloalkyl group which may be contained, if desired, in the arylsulfonium compound, is preferably a linear or branched alkyl group having 1 to 15 carbon atoms or a cycloalkyl group having 3 to 15 carbon atoms, for example, a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of each of R₂₀₁ to R₂₀₃ may have an alkyl group (for example, an alkyl group having 1 to 15 carbon atoms), a cycloalkyl group (for example, a cycloalkyl group having 3 to 15 carbon atoms), an aryl group (for example, an aryl group having 6 to 14 carbon atoms), an alkoxy group (for example, an alkoxy group having 1 to 15 carbon atoms), a halogen atom, a hydroxyl group, or a phenylthio group as a substituent.

Next, the compound (ZI-2) will be described.

The compound (ZI-2) is a compound in which R₂₀₁ to R₂₀₃ in Formula (ZI) each independently represent an organic group not having an aromatic ring. Here, the aromatic ring also encompasses an aromatic ring containing a heteroatom.

The organic group, as each of R₂₀₁ to R₂₀₃, containing no aromatic ring has generally 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and particularly preferably a linear or branched 2-oxoalkyl group.

Preferred examples of the alkyl group and the cycloalkyl group of each of R₂₀₁ to R₂₀₃ include a linear or branched alkyl group having 1 to 10 carbon atoms (for example, a methyl group, an ethyl group, a propyl group, a butyl group, and a pentyl group), and a cycloalkyl group having 3 to 10 carbon atoms (a cyclopentyl group, a cyclohexyl group, and a norbornyl group).

R₂₀₁ to R₂₀₃ may further be substituted with a halogen atom, an alkoxy group (for example, an alkoxy group having 1 to 5 carbon atoms), a hydroxyl group, a cyano group, or a nitro group.

Next, the compound (ZI-3) will be described.

The compound (ZI-3) is a compound represented by General Formula (ZI-3), which is a compound having a phenacylsulfonium salt structure.

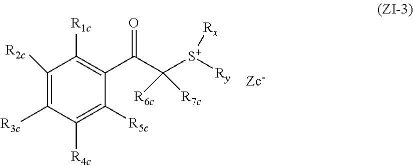

In General Formula (ZI-3),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Among any two or more members out of R_{1c} to R_{5c}, R_{5c} and R_{6c}, R_{6c} and R_{7c}, R_{5c} and Rₓ, and Rₓ and R_{y} each may be bonded to each other to form a ring structure, and the ring structure may contain an oxygen atom, a sulfur atom, a ketone group, an ester bond, or an amide bond.

Examples of the ring structure include an aromatic or non-aromatic hydrocarbon ring, an aromatic or non-aromatic heterocycle, or a polycyclic fused ring composed of two or more of these rings. Examples of the ring structure include 3- to 10-membered rings, and the ring structures are preferably 4- to 8-membered ring, and more preferably 5- or 6-membered rings.

Examples of groups formed by the bonding of any two or more of R_{1c} to R_{5c}, R_{6c} and R_{7c}, and Rₓ and R_{y} include a butylene group and a pentylene group.

As groups formed by the bonding of R_{5c} and R_{6c}, and R_{5c} and Rₓ, a single bond or alkylene group is preferable, and examples thereof include a methylene group and an ethylene group.

Zc⁻ represents an anion in General Formula (3), and specifically, is the same as described above.

Specific examples of the alkoxy group in the alkoxycarbonyl group as each of R_{1c} to R_{5c} are the same as the specific examples of the alkoxy group as each of R_{1c} to R_{5c}.

Specific examples of the alkyl group in the alkylcarbonyloxy group and the alkylthio group as each of R_{1c} to R_{5c} are the same as the specific examples of the alkyl group as each of R_{1c} to R_{5c}.

Specific examples of the cycloalkyl group in the cycloalkylcarbonyloxy group as each of R_{1c} to R_{5c} are the same as the specific examples of the cycloalkyl group as each of R_{1c} to R_{5c}.

Specific examples of the aryl group in the aryloxy group and the arylthio group as each of R_{1c} to R_{5c} are the same as the specific examples of the aryl group as each of R_{1c} to R_{5c}.

Examples of the cation in the compound (ZI-2) or (ZI-3) in the present invention include the cations described after paragraph [0036] of US2012/0076996A.

Next, the compound (ZI-4) will be described.

The compound (ZI-4) is represented by General Formula (ZI-4).

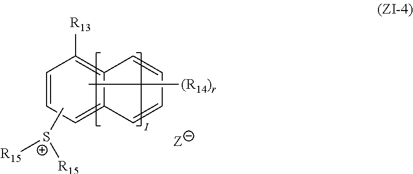

In General Formula (ZI-4),

R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

In a case where R₁₄'s are present in plural numbers, they each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have a substituent.

R₁₅'s each independently represent an alkyl group, a cycloalkyl group, or a naphthyl group. These groups may have a substituent. Two R₁₅'s may be bonded to each other to form a ring. In a case where two R₁₅'s are bonded to form a ring, the ring skeleton may include a heteroatom such as an oxygen atom and a nitrogen atom. In one embodiment, it is preferable that two R₁₅'s are alkylene groups, and are bonded to each other to form a ring structure.

l represents an integer of 0 to 2.

r represents an integer of 0 to 8.

Z⁻ represents an anion in General Formula (3), and specifically, is as described above.

In General Formula (ZI-4), as the alkyl group of each of R₁₃, R₁₄, and R₁₅, an alkyl which is linear or branched and has 1 to 10 carbon atoms is preferable, and preferred examples thereof include a methyl group, an ethyl group, an n-butyl group, and a t-butyl group.

Examples of the cation of the compound represented by General Formula (ZI-4) in the present invention include the cations described in paragraphs [0121], [0123], and [0124] of JP2010-256842A, paragraphs [0127], [0129], and [0130] of JP2011-76056A, and the like.

Next, General Formulae (ZII) and (ZIII) will be described.

In General Formulae (ZII) and (ZIII), R₂₀₄ to R₂₀₇ each independently represent an aryl group, an alkyl group, or a cycloalkyl group. The aryl group of each of R₂₀₄ to R₂₀₇ is preferably a phenyl group or a naphthyl group, and more preferably a phenyl group.

The aryl group of each of R₂₀₄ to R₂₀₇ may be an aryl group having a heterocyclic structure containing an oxygen atom, a nitrogen atom, a sulfur atom, or the like. Examples of the skeleton of the aryl group having a heterocyclic structure include pyrrole, furan, thiophene, indole, benzofuran, and benzothiophene.

Preferred examples of the alkyl group and the cycloalkyl group in each of R₂₀₄ to R₂₀₇ include linear or branched alkyl groups having 1 to 10 carbon atoms (for example, a methyl group, an ethyl group, a propyl group, a butyl group, and a pentyl group), and cycloalkyl groups having 3 to 10 carbon atoms (a cyclopentyl group, a cyclohexyl group, and a norbornyl group).

The aryl group, the alkyl group, or the cycloalkyl group of each of R₂₀₄ to R₂₀₇ may have a substituent. Examples of the substituent which the aryl group, the alkyl group, or the cycloalkyl group of each of R₂₀₄ to R₂₀₇ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z⁻ represents an anion in General Formula (3), and specifically, is as described above.

The acid generator (including a specific acid generator, which applies hereinafter) may be in a form of a low-molecular-weight compound or in a form incorporated into a part of a polymer. Further, a combination of the form of a low-molecular-weight compound and the form incorporated into a part of a polymer may also be used.

In a case where the acid generator is in the form of a low-molecular-weight compound, the molecular weight is preferably 580 or more, more preferably 600 or more, still more preferably 620 or more, and particularly preferably 640 or more. The upper limit is not particularly limited, but is preferably 3,000 or less, more preferably 2,000 or less, and still more preferably 1,000 or less.

In a case where the acid generator is in the form incorporated into a part of a polymer, it may be incorporated into a part of the above-mentioned resin or into a resin other than the resin.

The acid generator can be synthesized by a known method, and can be synthesized in accordance with, for example, the method described in JP2007-161707A.

The acid generator may be used singly or in combination of two or more kinds thereof.

The content of the acid generator (a total sum of contents in a case where the acid generators are present in plural kinds) in the composition is preferably 0.1% to 30% by mass, more preferably 0.5% to 25% by mass, still more preferably 3% to 20% by mass, and particularly preferably 3% to 15% by mass, with respect to the total solid contents of the composition.

In a case where the compound represented by General Formula (ZI-3) or (ZI-4) is included as the acid generator, the content of the acid generator (a total sum of the contents in a case where the acid generators are present in plural kinds) included in the composition is preferably 5% to 35% by mass, more preferably 8% to 30% by mass, still more preferably 9% to 30% by mass, and particularly preferably 9% to 25% by mass, with respect to the total solid contents of the composition.

[3] Hydrophobic Resin

The composition of the present invention may contain a hydrophobic resin (hereinafter also referred to as a “hydrophobic resin (D)” or simply a “resin (D)”). Further, the hydrophobic resin (D) is preferably different from the specific resin.

Although the hydrophobic resin (D) is preferably designed to be unevenly distributed on an interface as described above, it does not necessarily have to have a hydrophilic group in its molecule as different from the surfactant, and does not need to contribute to uniform mixing of polar/nonpolar materials.

Examples of the effect of addition of the hydrophobic resin include control of the static/dynamic contact angle of the resist film surface with respect to water, improvement of the immersion liquid tracking properties, and suppression of out gas.

The hydrophobic resin (D) preferably has at least one of a “fluorine atom”, a “silicon atom”, or a “CH₃ partial structure which is contained in a side chain moiety of a resin” from the viewpoint of uneven distribution on the film surface layer, and more preferably has two or more kinds.

In a case where hydrophobic resin (D) includes a fluorine atom and/or a silicon atom, the fluorine atom and/or the silicon atom in the hydrophobic resin (D) may be contained in the main chain or the side chain of the resin.

In a case where the hydrophobic resin (D) contains a fluorine atom, the resin is preferably a resin which contains an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom and the aryl group having a fluorine atom are a cycloalkyl group in which one hydrogen atom is substituted with a fluorine atom, and an aryl group having a fluorine atom, respectively, and may further have a substituent other than a fluorine atom.

Preferred examples of the alkyl group having a fluorine atom, the cycloalkyl group having a fluorine atom, and the aryl group having a fluorine atom include groups represented by General Formulae (F2) to (F4), but the present invention is not limited thereto.

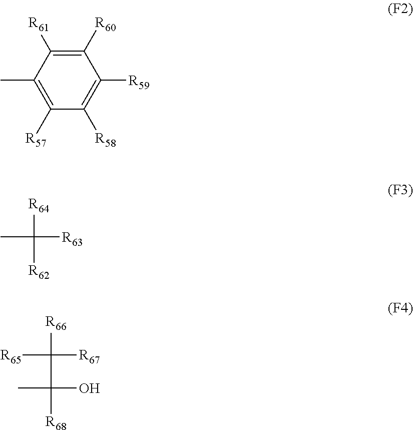

In General Formulae (F2) to (F4),

R₅₇ to R₆₈ each independently represent a hydrogen atom, a fluorine atom, or an (linear or branched) alkyl group, a provided that at least one of R₅₇, . . . , or R₆₁, at least one of R₆₂, . . . , or R₆₄, and at least one of R₆₅, . . . , or R₆₈ each independently represent a fluorine atom or an alkyl group (preferably having 1 to 4 carbon atoms) in which at least one hydrogen atom is substituted with a fluorine atom.

It is preferable that all of R₅₇ to R₆₁, and R₆₅ to R₆₇ are fluorine atoms. R₆₂, R₆₃, and R₆₈ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

The hydrophobic resin (D) may contain a silicon atom. It is preferably a resin having, as the partial structure having a silicon atom, an alkylsilyl structure (preferably a trialkylsilyl group) or a cyclic siloxane structure.

Examples of the repeating unit having a fluorine atom or a silicon atom include those exemplified in [0519] of US2012/0251948A1.

Moreover, it is also preferable that the hydrophobic resin (D) contains a CH₃ partial structure in the side chain moiety as described above.

Here, the CH₃ partial structure (hereinafter also simply referred to as a “side chain CH₃ partial structure”) contained in the side chain moiety in the hydrophobic resin (D) includes a CH₃ partial structure contained in an ethyl group, a propyl group, and the like.

On the other hand, a methyl group bonded directly to the main chain of the hydrophobic resin (D) (for example, an α-methyl group in the repeating unit having a methacrylic acid structure) makes only a small contribution of uneven distribution to the surface of the hydrophobic resin (D) due to the effect of the main chain, and it is therefore not included in the CH₃ partial structure in the present invention.

More specifically, in a case where the hydrophobic resin (D) contains a repeating unit derived from a monomer having a polymerizable moiety with a carbon-carbon double bond, such as a repeating unit represented by General Formula (M), and in addition, R₁₁ to R₁₄ are CH₃ “themselves”, such CH₃ is not included in the CH₃ partial structure contained in the side chain moiety in the present invention.

On the other hand, a CH₃ partial structure which is present via a certain atom from a C—C main chain corresponds to the CH₃ partial structure in the present invention. For example, in a case where R₁₁ is an ethyl group (CH₂CH₃), the hydrophobic resin has “one” CH₃ partial structure in the present invention.

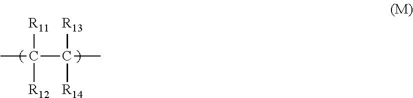

In General Formula (M),

R₁₁ to R₁₄ each independently represent a side chain moiety.

Examples of R₁₁ to R₁₄ in the side chain moiety include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

The hydrophobic resin (D) is preferably a resin including a repeating unit having the CH₃ partial structure in the side chain moiety thereof. Further, the hydrophobic resin more preferably has, as such a repeating unit, at least one repeating unit (x) selected from a repeating unit represented by General Formula (II) or a repeating unit represented by General Formula (III).

Hereinafter, the repeating unit represented by General Formula (II) will be described in detail.

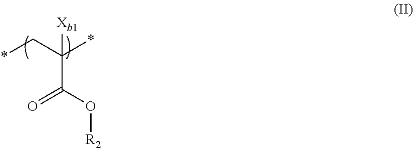

In General Formula (II), X_{b1} represents a hydrogen atom, an alkyl group, a cyano group, or a halogen atom, and R₂ represents an organic group which has one or more CH₃ partial structures and is stable against an acid. Here, it is preferable that the organic group which is stable against an acid is more specifically an organic group not having the “acid-decomposable group” described in the resin P.

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably from 2 to 10, and more preferably from 2 to 8.

Specific preferred examples of the repeating unit represented by General Formula (II) are set forth below, but the present invention is not limited thereto.

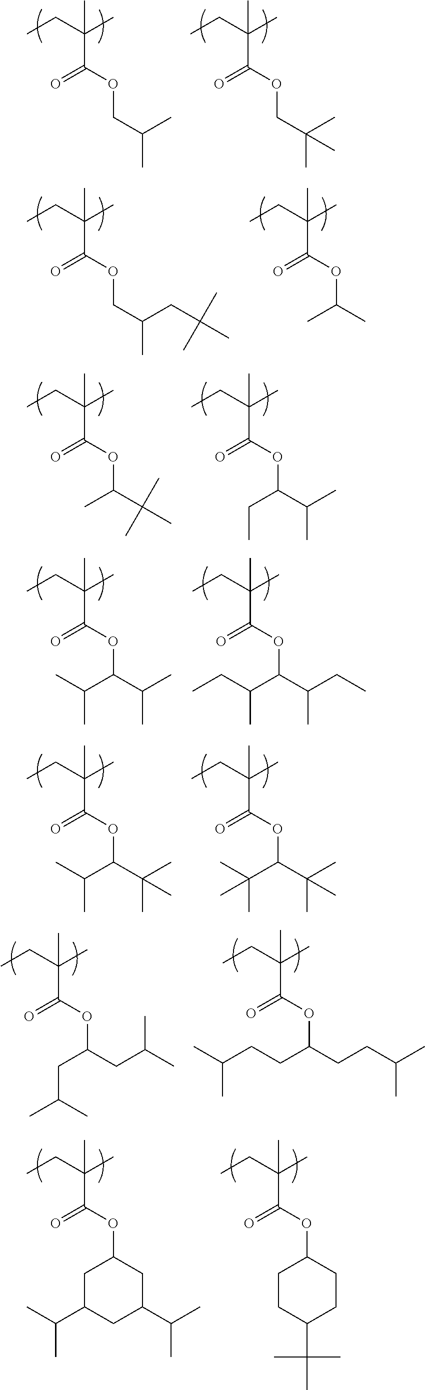

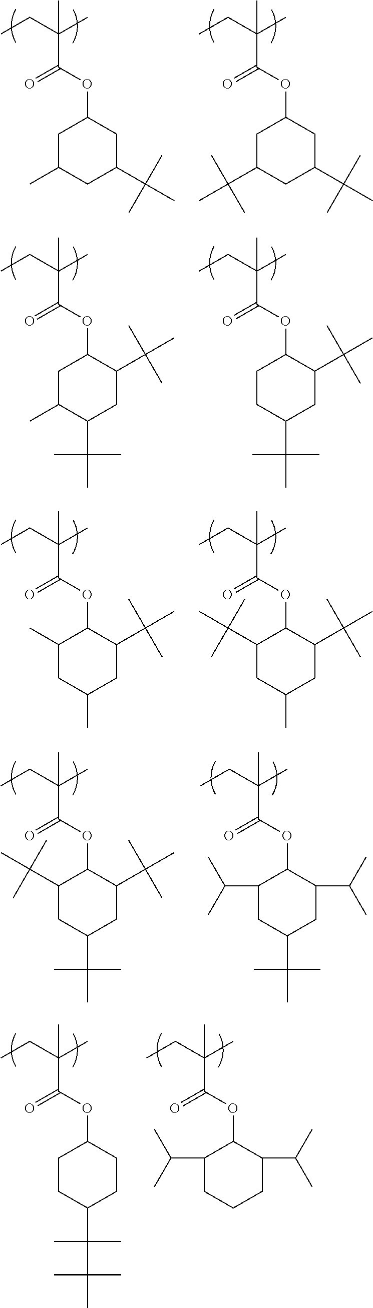

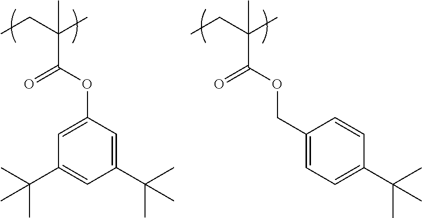

The repeating unit represented by General Formula (II) is preferably a repeating unit which is stable against an acid (non-acid-decomposable), and specifically, it is preferably a repeating unit not having a group capable of decomposing by the action of an acid to generate a polar group.

Hereinafter, the repeating unit represented by General Formula (III) will be described in detail.

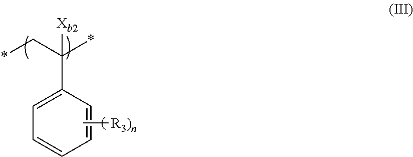

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group stable against an acid, it is preferable that R₃ is more specifically an organic group not having the “acid-decomposable group” described in the resin P.

Examples of R₃ include an alkyl group having one or more CH₃ partial structures.

The number of the CH₃ partial structures contained in the organic group which has one or more CH₃ partial structures and is stable against an acid as R₃ is preferably from 1 to 10, more preferably from 1 to 8, and still more preferably from 1 to 4.

n represents an integer of 1 to 5, more preferably 1 to 3, and still more preferably 1 or 2.

Specific preferred examples of the repeating unit represented by General Formula (III) are set forth below, but the present invention is not limited thereto.

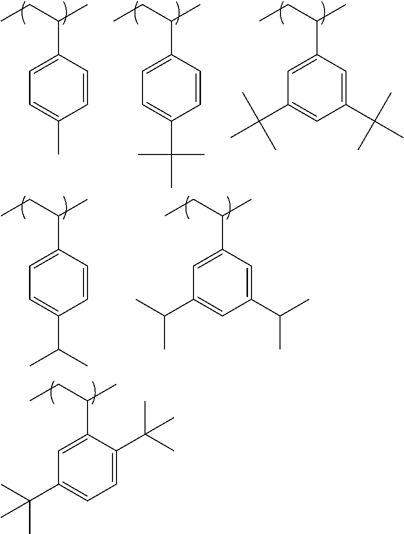

The repeating unit represented by General Formula (III) is preferably a repeating unit which is stable against an acid (non-acid-decomposable), and specifically, it is preferably a repeating unit which does not have a group capable of decomposing by the action of an acid to generate a polar group.

In a case where the hydrophobic resin (D) includes a CH₃ partial structure in the side chain moiety thereof, and in particular, it has neither a fluorine atom nor a silicon atom, the content of at least one repeating unit (x) of the repeating unit represented by General Formula (II) or the repeating unit represented by General Formula (III) is preferably 90% by mole or more, and more preferably 95% by mole or more, with respect to all the repeating units of the hydrophobic resin (D). Further, the content is usually 100% by mole or less with respect to all the repeating units of the hydrophobic resin (D).

By incorporating at least one repeating unit (x) of the repeating unit represented by General Formula (II) or the repeating unit represented by General Formula (III) in a proportion of 90% by mole or more with respect to all the repeating units of the hydrophobic resin (D) into the hydrophobic resin (D), the surface free energy of the hydrophobic resin (D) is increased. As a result, it is difficult for the hydrophobic resin (D) to be unevenly distributed on the surface of the resist film and the static/dynamic contact angle of the resist film with respect to water can be securely increased, thereby enhancing the immersion liquid tracking properties.

In addition, in a case where the hydrophobic resin (D) contains (i) a fluorine atom and/or a silicon atom or (ii) a CH₃ partial structure in the side chain moiety, the hydrophobic resin (D) may have at least one group selected from the following groups (x) to (z):

(x) an acid group,

(y) a group having a lactone structure, an acid anhydride group, or an acid imido group, and

(z) a group capable of decomposing by the action of an acid.

Examples of the acid group (x) include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the acid group include a fluorinated alcohol group (preferably a hexafluoroisopropanol group), a sulfonimido group, and a bis(alkylcarbonyl)methylene group.

Examples of the repeating unit containing an acid group (x) include a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the polymer chain terminal by using a polymerization initiator or chain transfer agent containing an acid group during the polymerization, either of which is preferable.

The repeating unit having an acid group (x) may have at least one of a fluorine atom or a silicon atom. The content of the repeating units having an acid group (x) is preferably 1% to 50% by mole, more preferably 3% to 35% by mole, and still more preferably 5% to 20% by mole, with respect to all the repeating units in the hydrophobic resin (D).

Specific examples of the repeating unit having an acid group (x) are set forth below, but the present invention is not limited thereto. In the formulae, Rx represents a hydrogen atom, CH₃, CF₃, or CH₂OH.

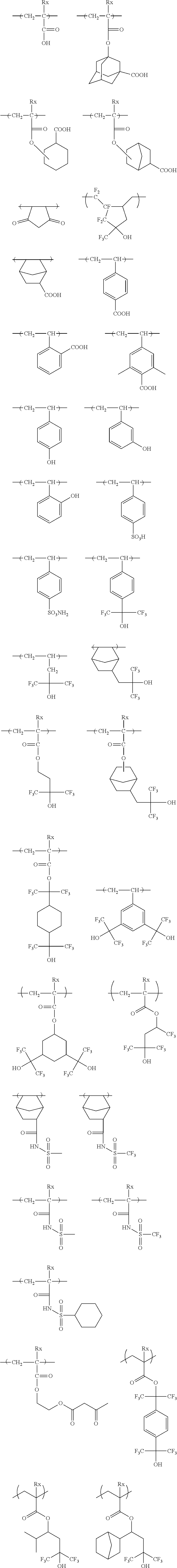

As the group having a lactone structure, the acid anhydride group, or the acid imido group (y), a group having a lactone structure is particularly preferable.

The repeating unit including such a group is, for example, a repeating unit in which the group is directly bonded to the main chain of the resin, such as a repeating unit by an acrylic acid ester or a methacrylic acid ester. This repeating unit may be a repeating unit in which the group is bonded to the main chain of the resin through a linking group. Alternatively this repeating unit may be introduced into the terminal of the resin by using a polymerization initiator or chain transfer agent containing the group during the polymerization.

Examples of the repeating unit having a group having a lactone structure include the same ones as the repeating unit having a lactone structure, other than the specific repeating units, as described earlier in the section of the specific resin.

The content of the repeating units having a group having a lactone structure, an acid anhydride group, or an acid imido group is preferably 1% to 100% by mole, more preferably 3% to 98% by mole, and still more preferably 5% to 95% by mole, with respect to all the repeating units in the hydrophobic resin (D).

With respect to the hydrophobic resin (D), examples of the repeating unit having a group (z) capable of decomposing by the action of an acid include the same ones as the repeating units having an acid-decomposable group, as mentioned with respect to the specific resin. The repeating unit having a group (z) capable of decomposing by the action of an acid may have at least one of a fluorine atom or a silicon atom. With respect to the hydrophobic resin (D), the content of the repeating units having a group (z) capable of decomposing by the action of an acid is preferably 1% to 80% by mole, more preferably 10% to 80% by mole, and still more preferably 20% to 60% by mole, with respect to all the repeating units in the resin (D).

The hydrophobic resin (D) may further have repeating units different from the above-mentioned repeating units.

The content of the repeating units including a fluorine atom is preferably 10% to 100% by mole, and more preferably 30% to 100% by mole, with respect to all the repeating units included in the hydrophobic resin (D). Further, the content of the repeating units including a silicon atom is preferably 10% to 100% by mole, and more preferably 20% to 100% by mole, with respect to all the repeating units included in the hydrophobic resin (D).

On the other hand, in particular, in a case where the hydrophobic resin (D) includes a CH₃ partial structure in the side chain moiety thereof, it is also preferable that the hydrophobic resin (D) has a form not having substantially any one of a fluorine atom and a silicon atom. Further, it is preferable that the hydrophobic resin (D) is substantially composed of only repeating units, which are composed of only atoms selected from a carbon atom, an oxygen atom, a hydrogen atom, a nitrogen atom, and a sulfur atom.

The weight-average molecular weight of the hydrophobic resin (D) in terms of standard polystyrene is preferably 1,000 to 100,000, and more preferably 1,000 to 50,000.

Furthermore, the hydrophobic resins (D) may be used singly or in combination of plural kinds thereof.

The content of the hydrophobic resin (D) in the composition is preferably 0.01% to 10% by mass, and more preferably 0.05% to 8% by mass, with respect to the total solid contents of the composition of the present invention.

In the hydrophobic resin (D), the content of residual monomers or oligomer components is also preferably 0.01% to 5% by mass, and more preferably 0.01% to 3% by mass. Further, the molecular weight distribution (Mw/Mn, also referred to as a dispersity) is preferably in the range of 1 to 5, and more preferably in the range of 1 to 3.

As the hydrophobic resin (D), various commercially available products may also be used, or the resin may be synthesized by an ordinary method (for example, radical polymerization).

[4] Acid Diffusion Control Agent

The composition of the present invention preferably contains an acid diffusion control agent. The acid diffusion control agent acts as a quencher that inhibits a reaction of the acid-decomposable resin in the unexposed area by excessive generated acids by trapping the acids generated from an acid generator or the like upon exposure. As the acid diffusion control agent, a basic compound, a low-molecular-weight compound which has a nitrogen atom and a group that leaves by the action of an acid, a basic compound whose basicity is reduced or lost upon irradiation with actinic rays or radiation, or an onium salt which becomes a relatively weak acid relative to the acid generator can be used.

Preferred examples of the basic compound include compounds having structures represented by Formulae (A) to (E).

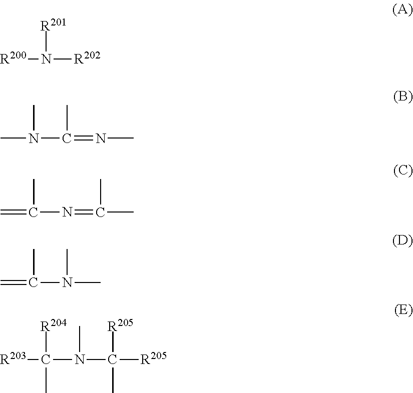

In General Formulae (A) and (E),

R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), and R²⁰¹ and R²⁰² may be bonded to each other to form a ring.

R²⁰³, R²⁰⁴, R²⁰⁵, and R²⁰⁶ may be the same as or different from each other, and each represent an alkyl group having 1 to 20 carbon atoms.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl groups in General Formulae (A) and (E) are more preferably unsubstituted.

Preferred examples of the compound include guanidine, aminopyrrolidine, pyrazole, pyrazoline, piperazine, aminomorpholine, aminoalkylmorpholine, and piperidine. More preferred examples of the compound include a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; and an aniline derivative having a hydroxyl group and/or an ether bond.

Specific preferred examples of the compound include the compounds exemplified in paragraph [0379] in US2012/0219913A1.

Preferred examples of the basic compound include an amine compound having a phenoxy group, an ammonium salt compound having a phenoxy group, an amine compound having a sulfonic acid ester group, and an ammonium salt compound having a sulfonic acid ester group.

These basic compounds may be used singly or in combination of two or more kinds thereof.

The composition of the present invention may or may not contain the basic compound, but in a case where it contains the basic compound, the content of the basic compound is usually 0.001% to 10% by mass, and preferably 0.01% to 5% by mass, with respect to the solid content of the composition.

The ratio between the acid generator to the basic compound to be used in the composition, in terms of a molar ratio (acid generator/basic compound), is preferably 2.5 to 300, more preferably 5.0 to 200, and still more preferably 7.0 to 150.

The low-molecular-weight compound (hereinafter referred to as a “compound (C)”) which has a nitrogen atom and a group that leaves by the action of an acid is preferably an amine derivative having a group that leaves by the action of an acid on a nitrogen atom.

As the group that leaves by the action of an acid, an acetal group, a carbonate group, a carbamate group, a tertiary ester group, a tertiary hydroxyl group, or a hemiaminal ether group are preferable, and a carbamate group or a hemiaminal ether group is particularly preferable.

The molecular weight of the compound (C) is preferably 100 to 1,000, more preferably 100 to 700, and particularly preferably 100 to 500.

The compound (C) may have a carbamate group having a protecting group on a nitrogen atom. The protecting group constituting the carbamate group can be represented by General Formula (d-1).

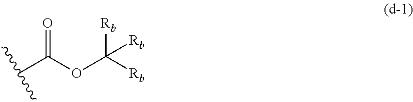

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be linked to each other to form a ring.

The alkyl group, the cycloalkyl group, the aryl group, or the aralkyl group represented by R_{b} may be substituted with a functional group such as a hydroxyl group, a cyano group, an amino group, a pyrrolidino group, a piperidino group, a morpholino group, and an oxo group, an alkoxy group, or a halogen atom. This shall apply to the alkoxyalkyl group represented by R_{b}.

R_{b} is preferably a linear or branched alkyl group, a cycloalkyl group, or an aryl group, and more preferably a linear or branched alkyl group, or a cycloalkyl group.

Examples of the ring formed by the mutual linking of two R_{b}'s include an alicyclic hydrocarbon group, an aromatic hydrocarbon group, a heterocyclic hydrocarbon group, and derivatives thereof.

Examples of the specific structure of the group represented by General Formula (d-1) include, but are not limited to, the structures disclosed in paragraph [0466] in US2012/0135348A1.

It is particularly preferable that the compound (C) has a structure of General Formula (6).

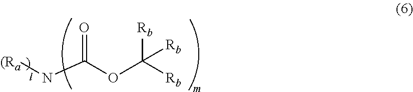

In General Formula (6), Rₐ represents a hydrogen atom, an alkyl group, a cycloalkyl group, an aryl group, or an aralkyl group. In a case where 1 is 2, two Rₐ's may be the same as or different from each other. Two Rₐ's may be linked to each other to form a heterocycle may be bonded to each other to form, together with a carbon atom to which they are bonded with the nitrogen atom in the formula. The heterocycle may contain a heteroatom other than the nitrogen atom in the formula.

R_{b} has the same meaning as R_{b} in General Formula (d-1), and preferred examples are also the same.

l represents an integer of 0 to 2, and m represents an integer of 1 to 3, satisfying l+m=3.

In General Formula (6), the alkyl group, the cycloalkyl group, the aryl group, and the aralkyl group as Rₐ may be substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (such the alkyl group, a cycloalkyl group, an aryl group, and aralkyl group may be substituted with the groups as described above) of Rₐ include the same groups as the specific examples as described above with respect to R_{b}.

Specific examples of the particularly preferred compound (C) in the present invention include, but are not limited to, the compounds disclosed in paragraph [0475] in US2012/0135348A1.

The compounds represented by General Formula (6) can be synthesized in accordance with JP2007-298569A, JP2009-199021A, and the like.

In the present invention, the low-molecular-weight compound (C) having a group that leaves by the action of an acid on a nitrogen atom may be used singly or in combination of two or more kinds thereof.

The content of the compound (C) in the composition of the present invention is preferably 0.001% to 20% by mass, more preferably 0.001% to 10% by mass, and still more preferably 0.01% to 5% by mass, with respect to the total solid contents of the composition.

The basic compound whose basicity is reduced or lost upon irradiation with actinic rays or radiation (hereinafter also referred to as a “compound (PA)”) is a compound which has a functional group with proton-accepting properties, and decomposes under irradiation with actinic rays or radiation to exhibit deterioration in proton-accepting properties, no proton-accepting properties, or a change from the proton-accepting properties to acidic properties.

The functional group with proton-accepting properties refers to a functional group having a group or an electron which is capable of electrostatically interacting with a proton, and for example, means a functional group with a macrocyclic structure, such as a cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following formula.

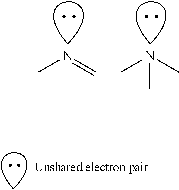

Preferred examples of the partial structure of the functional group with proton-accepting properties include crown ether, azacrown ether, primary to tertiary amines, pyridine, imidazole, and pyrazine structures.

The compound (PA) decomposes upon irradiation with actinic rays or radiation to generate a compound exhibiting deterioration in proton-accepting properties, no proton-accepting properties, or a change from the proton-accepting properties to acidic properties. Here, exhibiting deterioration in proton-accepting properties, no proton-accepting properties, or a change from the proton-accepting properties to acidic properties means a change of proton-accepting properties due to the proton being added to the functional group with proton-accepting properties, and specifically a decrease in the equilibrium constant at chemical equilibrium in a case where a proton adduct is generated from the compound (PA) having the functional group with proton-accepting properties and the proton.

The proton-accepting properties can be confirmed by carrying out pH measurement.

In the present invention, the acid dissociation constant pKa of the compound generated by the decomposition of the compound (PA) upon irradiation with actinic rays or radiation preferably satisfies pKa<−1, more preferably −13<pKa<−1, and still more preferably −13<pKa<−3.

In the present invention, the acid dissociation constant pKa indicates an acid dissociation constant pKa in an aqueous solution, and is described, for example, in Chemical Handbook (II) (Revised 4^{th} Edition, 1993, compiled by the Chemical Society of Japan, Maruzen Company, Ltd.), and a lower value thereof indicates higher acid strength. Specifically, the pKa in an aqueous solution may be measured by using an infinite-dilution aqueous solution and measuring the acid dissociation constant at 25° C., or a value based on the Hammett substituent constants and the database of publicly known literature data can also be obtained by computation using the following software package 1. All the values of pKa described in the present specification indicate values determined by computation using this software package.

Software package 1: Advanced Chemistry Development (ACD/Labs) Software V 8.14 for Solaris (1994-2007 ACD/Labs).

The compound (PA) generates a compound represented by General Formula (PA-1), for example, as the proton adduct generated by decomposition upon irradiation with actinic rays or radiation. The compound represented by General Formula (PA-1) is a compound exhibiting deterioration in proton-accepting properties, no proton-accepting properties, or a change from the proton-accepting properties to acidic properties since the compound has a functional group with proton-accepting properties as well as an acidic group, as compared with the compound (PA).

Q-A-(X)ₙ—B—R (PA-1)

In General Formula (PA-1),

Q represents —SO₃H, —CO₂H, or —W₁NHW₂R_{f}, in which R_{f} represents an alkyl group (preferably having 1 to 20 carbon atoms), a cycloalkyl group (preferably having 3 to 20 carbon atoms), or an aryl group (preferably having 6 to 30 carbon atoms), and W₁ and W₂ each independently represent —SO₂— or —CO—.

A represents a single bond or a divalent linking group.

X represents —SO₂— or —CO—.

n is 0 or 1.

B represents a single bond, an oxygen atom, or —N(Rₓ)R_{y}—, in which Rₓ represents a hydrogen atom or a monovalent organic group, and R_{y} represents a single bond or a divalent organic group, a provided that Rₓ may be bonded to R_{y} to form a ring or may be bonded to R to form a ring.

R represents a monovalent organic group having a functional group with proton-accepting properties.

The compound (PA) is preferably an ionic compound. The functional group with proton-accepting properties may be included in an anion moiety or a cation moiety, but is preferably included in the anion moiety.

Furthermore, in the present invention, compounds (PA) other than a compound capable of generating the compound represented by General Formula (PA-1) can also be appropriately selected. For example, a compound having a proton-accepting moiety at its cation moiety may be used as an ionic compound. More specific examples thereof include a compound represented by General Formula (7).

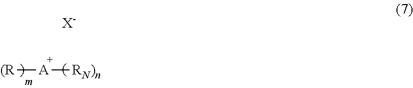

In the formula, A represents a sulfur atom or an iodine atom.

m represents 1 or 2 and n represents 1 or 2, provided that m+n=3 in a case where A is a sulfur atom and that m+n=2 in a case where A is an iodine atom.

R represents an aryl group.

R_{N} represents an aryl group substituted with the functional group with proton-accepting properties, and X⁻ represents a counter anion.

Specific examples of X⁻ include the same anions as those of the acid generators as described above.

Specific preferred examples of the aryl group of each of R and R_{N} include a phenyl group.

Specific examples of the functional group with proton-accepting properties contained in R_{N} are the same as those of the functional group with proton-accepting properties as described above in Formula (PA-1).

Specific examples of the ionic compounds having a proton acceptor site at a cationic moiety include the compounds exemplified in [0291] of US2011/0269072A1.

In addition, such compounds can be synthesized, for example, with reference to the methods described in JP2007-230913A, JP2009-122623A, and the like.

The compound (PA) may be used singly or in combination of two or more kinds thereof.

The content of the compound (PA) is preferably 0.1% to 10% by mass, and more preferably 1% to 8% by mass, with respect to the total solid content of the composition.

In the composition of the present invention, an onium salt which becomes a relatively weak acid with respect to the acid generator can be used as an acid diffusion control agent.

In a case of mixing the acid generator and the onium salt capable of generating an acid which is a relatively weak acid with respect to an acid generated from the acid generator, and then using the mixture, in a case where the acid generated from the acid generator upon irradiation with actinic rays or radiation collides with an onium salt having an unreacted weak acid anion, a weak acid is discharged by salt exchange, thereby generating an onium salt having a strong acid anion. In this process, the strong acid is exchanged with a weak acid having a lower catalytic ability, and therefore, the acid is deactivated in appearance, and thus, it is possible to carry out the control of acid diffusion.

As the onium salt which becomes a relatively weak acid with respect to the acid generator, compounds represented by General Formulae (d1-1) to (d1-3) are preferable.

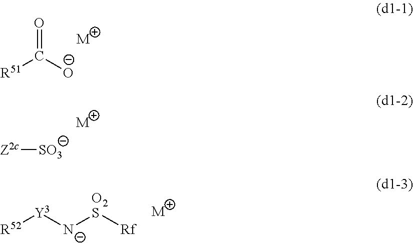

In the formulae, R⁵¹ is a hydrocarbon group which may have a substituent, Z^{2c} is a hydrocarbon group (provided that carbon adjacent to S is not substituted with a fluorine atom) having 1 to 30 carbon atoms, which may have a substituent, R⁵² is an organic group, Y³ is a linear, branched, or cyclic alkylene group or arylene group, Rf is a hydrocarbon group including a fluorine atom, and M⁺'s are each independently a sulfonium or iodonium cation.

Preferred examples of the sulfonium cation or the iodonium cation represented by M⁺ include the sulfonium cations exemplified by General Formula (ZI) and the iodonium cations exemplified by General Formula (ZII).

Preferred examples of the anionic moiety of the compound represented by General Formula (d1-1) include the structures exemplified in paragraph [0198] ofJP2012-242799A.

Preferred examples of the anionic moiety of the compound represented by General Formula (d1-2) include the structures exemplified in paragraph [0201] of JP2012-242799A.

Preferred examples of the anionic moiety of the compound represented by General Formula (d1-3) include the structures exemplified in paragraphs [0209] and [0210] of JP2012-242799A.

The onium salt which becomes a relatively weak acid with respect to the acid generator may be a compound (hereinafter also referred to as a “compound (CA)”) having a cationic moiety (C) and an anionic moiety in the same molecule, in which the cationic moiety and the anionic moiety are linked to each other through a covalent bond.

As the compound (CA), a compound represented by any one of General Formulae (C-1) to (C-3) is preferable.

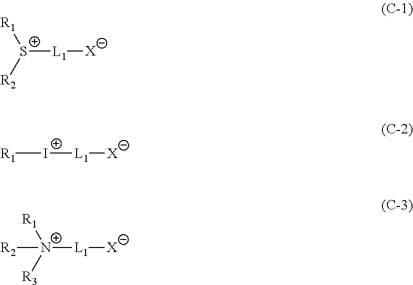

In General Formulae (C-1) to (C-3),

R₁, R₂, and R₃ represent a substituent having 1 or more carbon atoms.

L₁ represents a divalent linking group that links a cationic moiety with an anionic moiety, or a single bond.

—X⁻ represents an anionic moiety selected from —COO⁻, —SO₃⁻, —SO₂⁻, and —N⁻—R₄. R₄ represents a monovalent substituent having a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to one another to form a ring structure. Further, in (C-3), two members out of R₁ to R₃ may be combined to form a double bond with an N atom.

Examples of the substituent having 1 or more carbon atoms in each of R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, and preferably an alkyl group, a cycloalkyl group, and an aryl group.

Examples of L₁ as a divalent linking group include a linear or branched alkylene group, a cycloalkylene group, an arylene group, a carbonyl group, an ether bond, ester bond, amide bond, a urethane bond, a urea bond, and a group formed by a combination of two or more kinds of these groups. L₁ is more preferably alkylene group, an arylene group, an ether bond, ester bond, and a group formed by a combination of two or more kinds of these groups.

Preferred examples of the compound represented by General Formula (C-1) include the compounds exemplified in paragraphs [0037] to [0039] of JP2013-6827A and paragraphs [0027] to [0029] of JP2013-8020A.

Preferred examples of the compound represented by General Formula (C-2) include the compounds exemplified in paragraphs [0012] and [0013] of JP2012-189977A.

Preferred examples of the compound represented by General Formula (C-3) include the compounds exemplified in paragraphs [0029] to [0031] of JP2012-252124A.

The content of the onium salt which becomes a relatively weak acid with respect to the acid generator is preferably 0.5% to 10.0% by mass, more preferably 0.5% to 8.0% by mass, and still more preferably 1.0% to 8.0% by mass, with respect to the solid content of the composition.

[5] Solvent

The composition of the present invention usually contains a solvent.

Examples of the solvent which can be used in the preparation of the composition include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include the solvents described in [0441] to [0455] in US2008/0187860A.

In the present invention, a mixed solvent obtained by mixing a solvent containing a hydroxyl group and a solvent containing no hydroxyl group in the structure may be used as the organic solvent.

As the solvent containing a hydroxyl group and the solvent containing no hydroxyl group, the aforementioned exemplary compounds can be appropriately selected, but as the solvent containing a hydroxyl group, an alkylene glycol monoalkyl ether, alkyl lactate, and the like are preferable, and propylene glycol monomethyl ether (PGME, alternative name: 1-methoxy-2-propanol), ethyl lactate, and methyl 2-hydroxyisobutyrate are more preferable. Further, as the solvent containing no hydroxyl group, alkylene glycol monoalkyl ether acetate, alkyl alkoxy propionate, a monoketone compound which may contain a ring, cyclic lactone, alkyl acetate, and the like are preferable. Among these, propylene glycol monomethyl ether acetate (PGMEA, alternative name: 1-methoxy-2-acetoxypropane), ethyl ethoxypropionate, 2-heptanone, γ-butyrolactone, cyclohexanone, and butyl acetate are particularly preferable, and propylene glycol monomethyl ether acetate, ethyl ethoxypropionate, and 2-heptanone are most preferable.

The mixing ratio (mass ratio) of the solvent containing a hydroxyl group to the solvent containing no hydroxyl group is 1/99 to 99/1, preferably 10/90 to 90/10, and more preferably 20/80 to 60/40. A mixed solvent whose proportion of the solvent containing no hydroxyl group is 50% by mass or more is particularly preferable from the viewpoint of coating evenness.

The solvent preferably includes propylene glycol monomethyl ether acetate, and is preferably a solvent composed of propylene glycol monomethyl ether acetate singly or a mixed solvent of two or more kinds of solvents containing propylene glycol monomethyl ether acetate.

[6] Surfactant

The composition of the present invention may or may not further contain a surfactant. In a case where the composition contains the surfactant, it is more preferable that the composition contains any one of fluorine- and/or silicon-based surfactants (a fluorine-based surfactant, a silicon-based surfactant, and a surfactant having both a fluorine atom and a silicon atom).

By incorporating the surfactant into the composition of the present invention, it becomes possible to provide a resist pattern having improved adhesiveness and decreased development defects with good sensitivity and resolution in a case where an exposure light source of 250 nm or less, and particularly 220 nm or less, is used.

Examples of the fluorine- and/or silicon-based surfactants include the surfactants described in paragraph [0276] in US2008/0248425A.

In addition, in the present invention, surfactants other than the fluorine- and/or silicon-based surfactants described in paragraph [0280] in US2008/0248425A can also be used.

These surfactants may be used singly or in combination of a few surfactants.

In a case where the composition of the present invention contains a surfactant, the content of the surfactant is preferably 0.0001% to 2% by mass, and more preferably 0.0005% to 1% by mass, with respect to the total solid contents of the composition.

On the other hand, by setting the amount of the surfactant to be added to 10 ppm or less with respect to the total amount (excluding the solvent) of the composition, the hydrophobic resin is more unevenly distributed to the surface, so that the resist film surface can be made more hydrophobic, which can enhance the water tracking properties during the liquid immersion exposure.

[7] Other Additives

The composition of the present invention may or may not contain an onium carboxylate salt. Examples of such an onium carboxylate salt include those described in [0605] and [0606] in US2008/0187860A.

The onium carboxylate salt can be synthesized by reacting sulfonium hydroxide, iodonium hydroxide, ammonium hydroxide and carboxylic acid with silver oxide in a suitable solvent.

In a case where the composition of the present invention contains the onium carboxylate salt, the content of the salt is generally 0.1% to 20% by mass, preferably 0.5% to 10% by mass, and more preferably 1% to 7% by mass, with respect to the total solid contents of the composition.

The composition of the present invention may further contain an acid proliferation agent, a dye, a plasticizer, a light sensitizer, a light absorbent, an alkali-soluble resin, a dissolution inhibitor, a compound promoting solubility in a developer (for example, a phenol compound with a molecular weight of 1,000 or less, an alicyclic or aliphatic compound having a carboxyl group), and the like, as desired.

Such a phenol compound having a molecular weight of 1,000 or less can be easily synthesized by those skilled in the art with reference to the method described in, for example, JP1992-122938A (JP-H04-122938A), JP1990-28531A (JP-H02-28531A), U.S. Pat. No. 4,916,210A, EP219294B, or the like.

Specific examples of the alicyclic compound or aliphatic compound having a carboxyl group include, but not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

The concentration of the solid contents of the composition according to the present invention is usually 1.0% to 10% by mass, preferably 2.0% to 5.7% by mass, and more preferably 2.0% to 5.3% by mass. By setting the concentration of the solid contents to these ranges, it is possible to uniformly coat the resist solution on a substrate and additionally, it is possible to form a resist pattern having excellent line width roughness. The reason is not clear, but it is considered that, by setting the concentration of the solid contents to 10% by mass or less, and preferably 5.7% by mass or less, the aggregation of materials, particularly the photoacid generator, in the resist solution is suppressed, and as the result, it is possible to form a uniform resist film.

The concentration of the solid contents is the mass percentage of the mass of other resist components excluding the solvent with respect to the total mass of the composition.

A method for preparing the composition of the present invention is not particularly limited, but the composition is preferably prepared by dissolving the above-mentioned respective components in a predetermined organic solvent, and preferably in the mixed solvent, and filtering the solution through a filter. The filter for use in filtration through a filter is preferably a polytetrafluoroethylene-, polyethylene-, or nylon-made filter with a pore diameter of 0.1 μm or less, more preferably 0.05 μm or less, and still more preferably 0.03 μm or less. In the filtration through a filter, as described in, for example, JP2002-62667A, circulating filtration may be carried out, or the filtration may be carried out by connecting plural kinds of filters in series or in parallel. In addition, the composition may be filtered in plural times. Furthermore, the composition may be subjected to a deaeration treatment or the like before or after filtration through a filter.

The composition of the present invention relates to an actinic ray-sensitive or radiation-sensitive resin composition whose properties change by undergoing a reaction upon irradiation with actinic rays or radiation. More specifically, the present invention relates to an actinic ray-sensitive or radiation-sensitive resin composition which can be used in a step of manufacturing a semiconductor such as an IC, for manufacture of a circuit board for a liquid crystal, a thermal head, or the like, the manufacture of a mold structure for imprinting, other photofabrication processes, a planographic printing plate, or an acid-curable composition.

[Actinic Ray-Sensitive or Radiation-Sensitive Film]

The actinic ray-sensitive or radiation-sensitive film (resist film) of the present invention is a film formed using the above-mentioned composition of the present invention. Examples of a method for forming the film include a spin coating method, an extrusion die coating method, a blade coating method, a bar coating method, a screen printing method, a stencil printing method, a roll coating method, a curtain coating method, a spray coating method, a dip coating method, and an ink jet method.

[Pattern Forming Method]

The pattern forming method of the present invention (hereinafter also referred to as “the method of the present invention”) includes the following three steps.

(1) A film forming step of forming an actinic ray-sensitive or radiation-sensitive film (resist film) on a support, using the above-mentioned composition of the present invention

(2) An exposing step of exposing the actinic ray-sensitive or radiation-sensitive film (resist film)

(3) A developing step of developing the exposed actinic ray-sensitive or radiation-sensitive film (resist film) using a developer

[Step (1): Film Forming Step]

The step (1) is a film forming step of forming an actinic ray-sensitive or radiation-sensitive film (resist film) on a support, using the above-mentioned composition of the present invention. Specific examples of the method for forming the film is as described above.

<Support>

The support (preferably a substrate) is not particularly limited, and a substrate such as an inorganic substrate such as silicon, SiN, SiO₂, and SiN, and a coating type inorganic substrate such as spin on glass (SOG), which are generally used in a process for manufacturing a semiconductor such as an IC, a process for manufacturing a circuit board for a liquid crystal, a thermal head, or the like, and other lithographic processes of photofabrication can be used. In addition, an antireflection film may further be formed between the resist film and the substrate, as desired. As the antireflection film, a known organic or inorganic antireflection film can be appropriately used. Further, the pattern forming method of the present invention may be combined with a two-layer resist process, for example, as disclosed in JP2008-083384A, or may be combined with a process including performing multiple exposure and development as disclosed in WO2011/122336A. In a case where the present invention is combined with the process disclosed in WO2011/122336A, it is preferable that the pattern forming method of the present invention is applied as the second negative tone pattern forming method in Claim 1 of WO2011/122336A.

<Resist Film>

The thickness of the resist film is not particularly limited, but is preferably 1 to 500 nm, and more preferably 1 to 100 nm since a fine pattern with higher accuracy can be formed. By setting the concentration of the solid contents in the composition to an appropriate range to obtain a suitable viscosity, the coatability and the film forming properties can be improved, thereby providing such a film thickness.

[Step (2): Exposing Step]

The step (2) is a step of exposing the film (resist film) formed in the step (1) with actinic rays or radiation.

The light used for the exposure is not particularly limited, and examples thereof include infrared rays, visible light, ultraviolet rays, far ultraviolet rays, extreme ultraviolet rays, X-rays, and electron beams, preferably far ultraviolet rays at a wavelength of 250 nm or less, more preferably far ultraviolet rays at a wavelength of 220 nm or less, and still more preferably far ultraviolet rays at a wavelength of 1 to 200 nm.

More specific examples thereof include a KrF excimer laser (248 nm), an ArF excimer laser (193 nm), an F₂ excimer laser (157 nm), X-rays, EUV (13 nm), and electron beams. Among these, the KrF excimer laser, the ArF excimer laser, EUV, or the electron beams are preferable, and the ArF excimer laser is more preferable.

A liquid immersion exposure method can be applied to the exposing step. It is possible to combine the liquid immersion exposure method with super-resolution technology such as a phase shift method and a modified illumination method. The liquid immersion exposure can be carried out by the method described in, for example, paragraphs [0594] to [0601] of JP2013-242397A.

Moreover, in a case where the receding contact angle of the resist film formed using the composition of the present invention is extremely small, it cannot be suitably used in a case of carrying out exposure through a liquid immersion medium, and further, an effect of reducing watermark defect cannot be sufficiently exhibited. In order to realize a preferred receding contact angle, it is preferable to incorporate the hydrophobic resin (D) into the composition. Alternatively, a film (hereinafter also referred to as a “topcoat”) sparingly soluble in an immersion liquid, which is formed with the hydrophobic resin (D) on the upper layer of the resist film, may be provided on the upper layer of a resist film including the hydrophobic resin (D). The functions required for the topcoat are coating suitability on the upper layer part of the resist film, and sparing solubility in an immersion liquid. It is preferable that the topcoat is not mixed with the composition film and can be uniformly applied onto the upper layer of the composition film.

The topcoat is not particularly limited, and a topcoat known in the related art can be formed by a method known in the related art, and can be formed according to the description in, for example, paragraphs [0072] to [0082] of JP2014-059543A. Further, an embodiment in which a topcoat containing the basic compound described in JP2013-61648A is formed on a resist film is also preferable. In addition, even in a case of carrying out an exposure by a method other than the liquid immersion exposure method, the topcoat may be formed on the resist film.

In the liquid immersion exposure step, it is necessary for the immersion liquid to move on a wafer following the movement of an exposure head which scans the wafer at a high speed to form an exposed pattern. Therefore, the contact angle of the immersion liquid for the resist film in a dynamic state is important, and the resist is required to have a performance of allowing the immersion liquid to follow the high-speed scanning of an exposure head with no remaining of a liquid droplet.

The film irradiated with actinic rays or radiation in the step (2) after the step (2) and before the step (3) which will be described later may be subject to a heating treatment (PEB: post-exposure bake). The reaction in the exposed area in the present step is accelerated. The heating treatment (PEB) may be carried out plural times.

The temperature for the heating treatment is preferably 70° C. to 130° C., and more preferably 80° C. to 120° C.

The time for the heating treatment is preferably 30 to 300 seconds, more preferably 30 to 180 seconds, and still more preferably 30 to 90 seconds.

Heating treatment may be carried out using a means equipped in an ordinary exposure/development machine, or may also be carried out using a hot plate or the like.

[Step (3): Developing Step]

The step (3) is a step of developing the film exposed in the step (2) using a developer. The developer is not particularly limited, but for example, an alkali developer or a developer containing an organic solvent (hereinafter also referred to as an organic developer) can be used.

<Developer>

(Alkali Developer)

The alkali developer is not particularly limited, but examples thereof include the alkali developers described in paragraph [0460] of JP2014-048500A.

As the rinsing liquid in a rinsing treatment to be carried out after the alkali development, pure water is used, or an appropriate amount of a surfactant may be added thereto and the mixture may be used.

In addition, after the developing treatment or the rinsing treatment, a treatment for removing the developer or rinsing liquid adhering on the pattern by a supercritical fluid may be carried out.

(Organic Developer)

As the organic developer, a polar solvent such as a ketone-based solvent, an ester-based solvent, an alcohol-based solvent, an amide-based solvent, an ether-based solvent, and a hydrocarbon-based solvent can be used, and specific examples thereof include, in addition to those described in paragraphs [0461] to [0463] of JP2014-048500A, methyl 2-hydroxyisobutyrate, isobutyl isobutyrate, butyl propionate, butyl butanoate, and isoamyl acetate.

The solvents may used by mixing a plurality of the solvents or by mixing the solvent of water or solvents other than the solvents. However, in order to sufficiently exhibit the effects of the present invention, it is preferable that the moisture content in the entire developer is less than 10% by mass, but it is more preferable that the developer substantially does not contain water.

That is, the content of the organic solvent with respect to the organic developer is preferably from 90% by mass to 100% by mass, and preferably from 95% by mass to 100% by mass, with respect to the total amount of the developer.

In particular, the organic developer is preferably a developer containing at least one organic solvent selected from the group consisting of a ketone-based solvent, an ester-based solvent, an alcohol-based solvent, an amide-based solvent, and an ether-based solvent.

The vapor pressure of the organic developer at 20° C. is preferably 5 kPa or less, more preferably 3 kPa or less, and particularly preferably 2 kPa or less. By setting the vapor pressure of the organic developer to 5 kPa or less, the evaporation of the developer on the substrate or in a developing cup is suppressed, the temperature uniformity in the wafer surface is improved, and as a result, the dimensional uniformity within a wafer surface is improved.

It is possible to add an appropriate amount of a surfactant to the organic developer, as desired.

The surfactant is not particularly limited, but it is possible to use, for example, ionic or non-ionic fluorine- and/or silicon-based surfactants, or the like. Examples of the fluorine- and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and a non-ionic surfactant is preferable. The non-ionic surfactant is not particularly limited, but it is more preferable to use a fluorine-based surfactant or a silicon-based surfactant.

The amount of the surfactant to be used is usually 0.001% to 5% by mass, preferably 0.005% to 2% by mass, and more preferably 0.01% to 0.5% by mass, with respect to the total amount of the developer.

The organic developer may include a basic compound. Specific and preferred examples of the basic compound which can be included in the organic developer used in the present invention are the same as those for the basic compound which can be included in the composition of the present invention, as mentioned above as the acid diffusion control agent.

<Developing Method>

As the developing method, for example, a method in which a substrate is immersed in a tank filled with a developer for a certain period of time (a dip method), a method in which a developer is heaped up to the surface of a substrate by surface tension and developed by stopping for a certain period of time (a puddle method), a method in which a developer is sprayed on the surface of a substrate (a spray method), a method in which a developer is continuously discharged on a substrate spun at a constant rate while scanning a developer discharging nozzle at a constant rate (a dynamic dispense method), or the like, can be applied. Further, suitable ranges of the discharge pressure of the developer to be discharged, methods for adjusting the discharge pressure of the developer, and the like are not particularly limited, and for example, the ranges and the methods described in paragraphs [0631] to [0636] of JP2013-242397A can be used.

In the pattern forming method of the present invention, a combination of a step of carrying out development using a developer including an organic solvent (organic solvent developing step) and a step of carrying out development using an aqueous alkali solution (alkali developing step) may be used, whereby a finer pattern can be formed. By virtue of multiple development processes in which development is carried out in plural times in this manner, a pattern can be formed by keeping only a region with an intermediate exposure intensity from not being dissolved, so that a finer pattern than usual can be formed (the same mechanism as in paragraph [0077] of JP2008-292975A).

In the pattern forming method of the present invention, the order of the alkali developing step and the organic solvent developing step is not particularly limited, but the alkali development is more preferably carried out before the organic solvent developing step.

It is preferable that the method includes a step of carrying out washing using a rinsing liquid after the step of carrying out development using a developer including an organic solvent.

The rinsing liquid used in the rinsing step after the step of carrying out development using a developer including an organic solvent is not particularly limited as long as the rinsing liquid does not dissolve the resist pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent are the same as those described for the developer including an organic solvent.

After the step of carrying out development using a developer including an organic solvent, it is more preferable to carry out a step of carrying out washing using a rinsing liquid containing at least one organic solvent selected from the group consisting of a ketone-based solvent, an ester-based solvent, an alcohol-based solvent, an amide-based solvent, and a hydrocarbon-based solvent, it is still more preferable to carry out a step of carrying out washing using a rinsing liquid containing an alcohol-based solvent or an ester-based solvent, it is particularly preferable to carry out a step of carrying out washing using a rinsing liquid containing a monohydric alcohol, and it is most preferable to carry out a step of carrying out washing using a rinsing liquid containing a monohydric alcohol having 5 or more carbon atoms.

The rinsing liquid containing the hydrocarbon-based solvent is preferably a hydrocarbon compound having 6 to 30 carbon atoms, more preferably a hydrocarbon compound having 8 to 30 carbon atoms, and particularly preferably a hydrocarbon compound having 10 to 30 carbon atoms. By using a rinsing liquid including decane and/or undecane among these, pattern collapse is suppressed.

In a case where the ester-based solvent is used as the organic solvent, a glycol ether-based solvent may be used, in addition to the ester-based solvent (one kind or two or more kinds). Specific examples of such a case include use of an ester-based solvent (preferably butyl acetate) as a main component and a glycol ether-based solvent (preferably propylene glycol monomethyl ether (PGME)) as a side component. Thus, residue defects are suppressed.

Here, examples of the monohydric alcohol used in the rinsing step include linear, branched, or cyclic monohydric alcohols, and specifically, 1-butanol, 2-butanol, 3-methyl-1-butanol, tert-butyl alcohol, I-pentanol, 2-pentanol, I-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, or the like can be used. Further, 1-hexanol, 2-hexanol, 4-methyl-2-pentanol, 1-pentanol, 3-methyl-1-butanol, or the like can be used as a particularly preferred monohydric alcohol having 5 or more carbon atoms.

The respective components in plural numbers may be mixed, or the components may be mixed with an organic solvent other than the above solvents, and used.

The moisture content of the rinsing liquid is preferably 10% by mass or less, more preferably 5% by mass or less, and particularly preferably 3% by mass or less. By setting the moisture content to 10% by mass or less, good development characteristics can be obtained.

The vapor pressure at 20° C. of the rinsing liquid which is used after the step of carrying out development using a developer including an organic solvent is preferably from 0.05 kPa to 5 kPa, more preferably from 0.1 kPa to 5 kPa, and most preferably from 0.12 kPa to 3 kPa. By setting the vapor pressure of the rinsing liquid to a range from 0.05 kPa to 5 kPa, the temperature uniformity within a wafer surface is improved, and further, the dimensional uniformity within a wafer surface is enhanced by suppression of swelling due to the permeation of the rinsing liquid.

The rinsing liquid can also be used after adding an appropriate amount of a surfactant thereto.

In the rinsing step, the wafer which has been subjected to development using a developer including an organic solvent is subjected to a washing treatment using the rinsing liquid including an organic solvent. A method for the washing treatment is not particularly limited, and for example, a method in which a rinsing liquid is continuously discharged on a substrate rotated at a constant rate (a rotation application method), a method in which a substrate is immersed in a tank filled with a rinsing liquid for a certain period of time (a dip method), a method in which a rinsing liquid is sprayed on a substrate surface (a spray method), or the like, can be applied. Among these, a method in which a washing treatment is carried out using the rotation application method, and a substrate is rotated at a rotation speed of 2,000 rpm to 4,000 rpm after washing, thereby removing the rinsing liquid from the substrate, is preferable. Further, it is preferable that a heating step (post bake) is included after the rinsing step. The residual developer and the rinsing liquid between and inside the patterns are removed by the baking. The heating step after the rinsing step is carried out at typically 40° C. to 160° C., and preferably 70° C. to 95° C., and typically for 10 seconds to 3 minutes, and preferably for 30 seconds to 90 seconds.

It is preferable that various materials (for example, a resist solvent, a developer, a rinsing liquid, a composition for forming an antireflection film, and a composition for forming a topcoat) used in the composition of the present invention and the pattern forming method of the present invention do not include impurities such as metals. The content of the metal components included in these materials is preferably 1 part per million (ppm) or less, more preferably 100 parts per trillion (ppt) or less, still more preferably 10 ppt or less, and particularly preferably 1 ppt or less.

Examples of a method for removing impurities such as metals from the various materials include filtration using a filter. As for the filter pore diameter, the pore size is preferably 50 nm or less, more preferably 10 nm or less, and still more preferably 5 nm or less. As for the materials of a filter, a polytetrafluoroethylene-made filter, a polyethylene-made filter, and a nylon-made filter are preferable. In the step of filtration using a filter, plural kinds of filters may be connected in series or in parallel, and used. In a case of using plural kinds of filters, a combination of filters having different pore diameters and/or materials may be used. In addition, various materials may be filtered plural times, and the step of filtering plural times may be a circulatory filtration step.

Moreover, examples of the method for reducing the impurities such as metals included in the various materials include a method involving selecting raw materials having a small content of metals as raw materials constituting various materials, and a method involving subjecting raw materials constituting various materials to filtration using a filter. The preferred conditions for filtration using a filter, which is carried out for raw materials constituting various materials, are the same as described above.

In addition to the filtration using a filter, removal of impurities by an adsorbing material may be carried out, or a combination of filtration using a filter and an adsorbing material may be used. As the adsorbing material, known adsorbing materials can be used, and for example, inorganic adsorbing materials such as silica gel and zeolite, and organic adsorbing materials such as activated carbon can be used.

It is necessary to prevent the incorporation of metal impurities in the production process in order to reduce the impurities such as metals included in the various materials. Sufficient removal of metal impurities from a production device can be checked by measuring the content of metal components included in a washing liquid used to wash the production device. The content of the metal components included in the washing liquid after the use is preferably 100 parts per trillion (ppt) or less, more preferably 10 ppt or less, and particularly preferably 1 ppt or less.

An electrically conductive compound may be added to the organic treatment liquid (a resist solvent, a developer, a rinsing liquid, or the like) used in the composition of the present invention and the pattern forming method of the present invention in order to prevent failure of chemical liquid pipe and various parts (a filter, an O-ring, a tube, or the like) due to electrostatic charge, and subsequently generated electrostatic discharge. The electrically conductive compound is not particularly limited and examples thereof include methanol. The addition amount is not particularly limited, but from the viewpoint of maintaining preferred development characteristics, it is preferably 10% by mass or less, and more preferably 5% by mass or less. For members of the chemical liquid pipe, various pipes coated with stainless steel (SUS), or a polyethylene, polypropylene, or fluorine resin (a polytetrafluoroethylene or perfluoroalkoxy resin, or the like) that has been subjected to an antistatic treatment can be used. In the same manner, for the filter or the O-ring, polyethylene, polypropylene, or fluorine resin (a polytetrafluoroethylene or perfluoroalkoxy resin, or the like) that has been subjected to an antistatic treatment can be used.

A method for improving the surface roughness of a pattern may be applied to the pattern formed by the method of the present invention. Examples of the method for improving the surface roughness of a pattern include the method of treating a resist pattern by a plasma of a hydrogen-containing gas disclosed in WO2014/002808A1. In addition, known methods as described in JP2004-235468A, US2010/0020297A, JP2009-19969A, and Proc. of SPIE Vol. 832883280N-1 “EUV Resist Curing Technique for LWR Reduction and Etch Selectivity Enhancement” may be applied.

The pattern forming method of the present invention can be used for a guide pattern formation in a directed self-assembly (DSA) (see, for example, ACS Nano Vol. 4, No. 8, Pages 4815-4823).

In addition, a resist pattern formed by the method can be used as a core material (core) of the spacer process disclosed in JP1991-270227A (JP-H03-270227A) and JP2013-164509A.

In addition, the present invention further relates to a method for manufacturing an electronic device, including the above-described pattern forming method of the present invention, and an electronic device manufactured by the method for manufacturing an electronic device.

The electronic device of the present invention is suitably mounted on electric or electronic equipment (for example, home electronics, office automation (OA)-related equipment, media-related equipment, optical equipment, and telecommunication equipment).

### EXAMPLES

Hereinafter, the present invention will be described in more details with reference to Examples, but the present invention is not limited thereto.

### Synthesis Example

### Synthesis Example 1: Synthesis of Monomer A

5.00 g of 2-(methacryloxy)-acetic acid (1) and 6.36 g of dimethylaminopyridine (DMAP) were dissolved in 350 mL of dichloromethane at room temperature in a nitrogen atmosphere to obtain a solution. To the obtained solution was added 8.23 g of dicyclohexyl carbodiimide (DCC), then 3.65 g of furan-2,4(3H,5H)-dione was added thereto, and the solution was stirred for 3 hours. Thereafter, insoluble materials were removed from the solution by filtration through Celite, and then the filtrate was washed with 200 mL of 1 N HCl. The aqueous layer was recovered from the mixed liquid after washing, the aqueous layer was extracted three times with 200 mL of ethyl acetate, and dried over sodium sulfate, and then the solvent was removed by distillation to obtain 3.45 g of a desired monomer A.

¹H-NMR (nuclear magnetic resonance method), 400 MHz, δ ((CD₃)₂CO) ppm: 1.90 (3H, s), 4.17 (2H, s), 4.98 (2H, s), 5.66-5.69 (1H, m), 6.06 (1H, s))

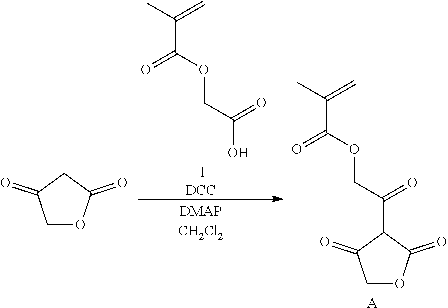

### Synthesis Example 2: Synthesis of Monomer B

9.69 g of 2-(methacryloxy)-acetic acid (1), 4.88 g of 2-oxazolidone, and 0.82 g of dimethylaminopyridine (DMAP) were dissolved in 105 mL of dichloromethane at room temperature in a nitrogen atmosphere. After the dissolution, the solution was cooled to 0° C., and 12.88 g of dicyclohexyl carbodiimide (DCC) was added thereto, and the solution was stirred for 1 hour. Thereafter, the solution was returned to room temperature, and further stirred for 2 hours. After the reaction, the solution and aqueous sodium bicarbonate were mixed, the solution was washed, and the organic layer was recovered from the mixed liquid, the organic layer was dried over sodium sulfate, and then the solvent was removed by distillation. The concentrated solution was purified (hexane/ethyl acetate=3/5) by column chromatography to obtain 4.5 g of a desired monomer B.

¹H-NMR, 400 MHz, 8 ((CDCl₃) ppm: 2.00 (3H, t), 4.05 (2H, t), 4.51 (2H, t), 5.27 (2H, s), 5.66-5.68 (1H, m), 6.23-6.25 (1H, m))

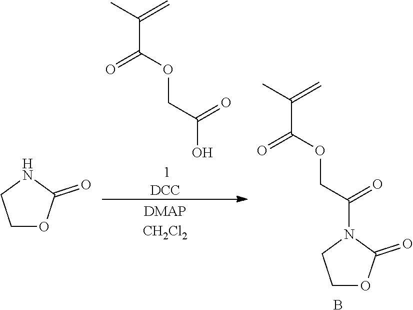

### Synthesis Example 3: Synthesis of Resin (1)

40.71 parts by mass of cyclohexanone was heated at 80° C. in a nitrogen stream. While stirring this liquid, a mixed solution of 6.79 parts by mass of monomers represented by Structural Formula A, 13.74 parts by mass of monomers represented by Structural Formula C, 75.60 parts by mass of cyclohexanone, and 0.92 parts by mass of dimethyl 2,2′-azobisisobutyrate [V-601, manufactured by Wako Pure Chemical Industries, Co., Ltd.] was added dropwise thereto for 6 hours. After completion of dropwise addition, the reaction solution was further stirred at 80° C. for 2 hours. The reaction solution was left to be cooled, and then reprecipitated and filtered with a large amount of heptane/ethyl acetate (mass ratio of 7:3), and the obtained solid was dried in vacuo to obtain 16.01 parts by mass of a resin (1) which is an acid-decomposable resin.

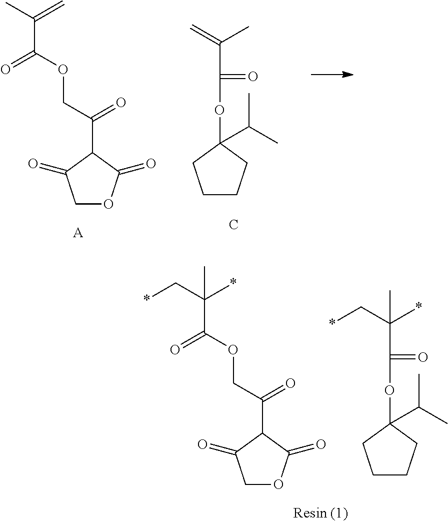

The weight-average molecular weight (Mw: in terms of polystyrene) and the dispersity determined by GPC (carrier: tetrahydrofuran (THF)) of the obtained resin (1) were Mw=11,000 and Mw/Mn=1.64, respectively. The compositional ratio (corresponding to the repeating units in order from the left side) measured by means of ¹³C-NMR was 30/70 (% by mole).

The same procedures as in Synthesis Examples 1 to 3 were carried out to synthesize resins (2) to (26) described below, which are acid-decomposable resins.

[Preparation of Resist Composition]

The components shown in Table 1 were dissolved in the solvents shown in the same table to prepare each of solutions at a concentration of the solid contents of 3.8% by mass, respectively. Subsequently, the obtained solution was filtered through a polyethylene filter with a pore size of 0.1 μm to prepare the actinic ray-sensitive or radiation-sensitive resin composition (resist composition) of each of Examples and Comparative Examples.

<SP Value>

Moreover, the dissolution parameters [(MPa)^{1/2}] of the monomers corresponding to the “repeating units derived from monomers having at least one of a lactone structure or an amide structure” included in the resins (resins (1) to (26)) contained in each of Examples and Comparative Examples are shown in Table 1. Further, in a case where the “repeating units derived from monomers having at least one of a lactone structure or an amide structure” are present in plural numbers, the highest value among the dissolution parameters of the corresponding monomers is shown. A method for calculating the dissolution parameter (SP value) is as described above.

<NO_{LX}/C_{LX}>

In addition, with regard to the “repeating units derived from monomers having at least one of a lactone structure or an amide structure” included in the resins (resins (1) to (26)) contained in each of Examples and Comparative Examples, the above-mentioned ratios (NO_{LX}/C_{LX}) are shown in Table 1. Further, in a case where the “repeating units derived from monomers having at least one of a lactone structure or an amide structure” are present in plural numbers, the ratio (NO_{LX}/C_{LX}) of the “repeating unit derived from monomer having at least one of a lactone structure or an amide structure”, derived from the monomer exhibiting the highest value among the dissolution parameters of the corresponding monomers, is shown.

[Evaluation]

<Formation of Pattern>

### Examples 1 to 24, and Comparative Examples 1 and 2: ArF Liquid Immersion Exposure (Exposure Condition 1)

An organic antireflection film ARC29SR (manufactured by Nissan Chemical Industries, Ltd.) was applied onto a silicon wafer, and baked at 205° C. over 60 seconds, thereby forming an antireflection film having a film thickness of 88 nm on the silicon wafer. The obtained resist composition was applied thereonto, and baked (PB: prebaked) at 90° C. over 60 seconds, thereby forming a resist film having a film thickness of 80 nm.

The obtained wafer was subjected to pattern exposure using an ArF excimer laser liquid immersion scanner (manufactured by ASML, XT1700i, NA1.20, Dipole, outer sigma 0.950, inner sigma 0.850, and Y deflection). Further, as a reticle, a 6% halftone mask with a line size=44 nm and line:space=1:1 was used. In addition, ultrapure water was used as an immersion liquid. Thereafter, the wafer was baked (PEB: post-exposure baked) at 90° C. for 60 seconds, and developed by puddling it with an organic developer (butyl acetate) for 30 seconds, and the wafer was rotated at a rotation speed of 4,000 rpm for 30 seconds to form a line-and-space pattern (pattern) having a pitch of 88 nm and a space width of 44 nm (line width of 44 nm).

### Examples 25 to 48, and Comparative Examples 3 and 4: ArF Dry Exposure (Exposure Condition 2)

The prepared resist composition was applied onto a 8-inch Si wafer (Si wafer with a diameter of 200 mm) having the organic antireflection film (ARC29A, manufactured by Brewer Science Ltd.) thereon, using a spin coater Act8 manufactured by Tokyo Electron Limited, and dried on a hot plate at 90° C. for 60 seconds to obtain a resist film with a film thickness of 80 nm.

The formed resist film was subjected to pattern exposure with an exposure mask (line/space=1/1), using an ArF exposure device (PAS5500/1100 manufactured by ASML, XT1700i, numerical apertures (NA) of 0.75, Dipole (double illumination), outer sigma 0.89, and inner sigma 0.65). After the irradiation, the resist film was heated on a hot plate at 110° C. for 60 seconds, and developed with an organic developer (butyl acetate) to form a 1:1 line-and-space pattern (pattern) having a line width of 75 nm.

<Evaluation of Collapse Performance>

The formed line-and-space pattern (pattern) was observed at varying exposure doses, using a critical dimension scanning electron microscope (SEM, S-9380II manufactured by Hitachi, Ltd.), and a minimum line dimension (nm) in which the pattern could be resolved without collapses was measured. A smaller value thereof means that a finer pattern can be formed, indicating better collapse performance. The results are shown in Table 1 (collapse performance). In addition, the evaluation standards are as follows. In practical use, AA, A, or B is preferable, AA or A is more preferable, and AA is still more preferable.

(Exposure Condition 1)
AA: The minimum line dimension is 35 nm or less
A: The minimum line dimension is more than 35 nm and 40 nm or less
B: The minimum line dimension is more than 40 nm and 50 nm or less
C: The minimum line dimension is more than 50 nm

(Exposure Condition 2)
AA: The minimum line dimension is 40 nm or less
A: The minimum line dimension is more than 40 nm and 45 nm or less
B: The minimum line dimension is more than 45 nm and 55 nm or less
C: The minimum line dimension is more than 55 nm

TABLE 1

| | Resist composition | | | | | | | | | |
|---|---|---|---|---|---|---|---|---|---|---|
| | | | Acid | | | | | | | |
| | | | diffusion | | | | | | | |
| | | Acid | control | Hydrophobic | | | | | | |
| | Resin | generator | agent | resin | Surfactant | Solvent | SP | NO_{LX}/ | Exposure | Collapse |
| | (10.0 g) | (g) | (g) | (0.05 g) | (10 mg) | (mass ratio) | value | C_{LX} | condition | performance |
| Example 1 | Resin (1) | A-1 (1.4) | C-1 (0.72) | 1b | None | A1/B1 = 90/10 | 25.6 | 0.83 | 1 | B |
| Example 2 | Resin (2) | A-2 (1.7) | C-7 (0.49) | 2b | None | A1/B1 = 90/10 | 24.8 | 1.00 | 1 | B |
| Example 3 | Resin (3) | A-5 (0.9)/A-11 (0.4) | C-3 (0.77) | 4b | None | A1/B1 = 90/10 | 25.3 | 1.00 | 1 | B |
| Example 4 | Resin (4) | A-5 (1.4) | C-3 (0.40) | 3b | W-1 | A1/B1 = 70/30 | 26.0 | 1.00 | 1 | AA |
| Example 5 | Resin (5) | A-1 (1.9) | C-5 (0.72) | 5b | None | A1/B1 = 70/30 | 26.0 | 1.00 | 1 | AA |
| Example 6 | Resin (6) | A-6 (1.4) | C-2 (0.21) | 1b | None | A1/A3 = 95/5 | 26.5 | 1.00 | 1 | A |
| Example 7 | Resin (7) | A-2 (1.1) | C-6 (0.22) | 4b | None | A1/A2 = 70/30 | 27.6 | 1.00 | 1 | AA |
| Example 8 | Resin (8) | A-8 (2.3) | C-6 (0.32) | 2b | None | A1/B1 = 80/20 | 27.6 | 1.00 | 1 | AA |
| Example 9 | Resin (9) | A-2 (1.5) | C-8 (0.72) | 3b | None | A1/B2 = 90/10 | 25.6 | 0.83 | 1 | B |
| Example 10 | Resin (10) | A-2 (1.6) | C-10 (0.72) | 4b | None | A1/A2 = 70/30 | 26.0 | 1.00 | 1 | AA |
| Example 11 | Resin (11) | A-3 (1.3) | C-2 (0.36) | 5b | W-2 | A1/A2 = 70/30 | 26.5 | 1.00 | 1 | A |
| Example 12 | Resin (12) | A-4 (2.3) | C-8 (0.72) | 5b | None | A1/A2 = 70/30 | 27.6 | 1.00 | 1 | AA |
| Example 13 | Resin (13) | A-3 (1.3) | C-6 (0.72) | 2b | W-1 | A1/A2 = 70/30 | 27.6 | 1.00 | 1 | AA |
| Example 14 | Resin (14) | A-9 (2.3) | C-1 (0.32) | 1b/2b | None | A1/A2 = 70/30 | 26.0 | 1.00 | 1 | AA |
| | | | | (0.02 g/0.03 g) | | | | | | |
| Example 15 | Resin (15) | A-1 (2.3) | C-2 (0.40) | 2b | W-2 | A1/B2 = 80/20 | 27.6 | 1.00 | 1 | AA |
| Example 16 | Resin (16) | A-10 (1.9) | C-3 (0.45) | 3b | None | A1/B2 = 80/20 | 27.6 | 1.00 | 1 | AA |
| Example 17 | Resin (17) | A-3 (1.3) | C-2 (0.40) | 4b | None | A1/B2 = 80/20 | 26.0 | 1.00 | 1 | AA |
| Example 18 | Resin (18) | A-1 (2.3) | C-5 (0.72) | 1b | W-3 | A1/B1 = 80/20 | 26.0 | 1.00 | 1 | AA |
| Example 19 | Resin (19) | A-2 (0.2)/A-5 (0.7) | C-2 (0.62) | 1b | W-1 | A1/A2 = 70/30 | 27.6 | 1.00 | 1 | AA |
| Example 20 | Resin (20) | A-2 (1.5) | C-2 (1.49) | 4b | W-3 | A1/A2 = 70/30 | 26.5 | 1.00 | 1 | A |
| Example 21 | Resin (21) | A-7 (1.4) | C-4 (0.45) | 4b | None | A1/A2 = 70/30 | 25.6 | 0.83 | 1 | B |
| Example 22 | Resin (22) | A-1 (2.3) | C-9 (0.21) | 1b | W-1 | A1/A2 = 70/30 | 26.0 | 1.00 | 1 | AA |
| Example 23 | Resin (23) | A-1 (2.3) | C-5 (0.72) | 1b | W-3 | A1/B1 = 80/20 | 27.6 | 1.00 | 1 | AA |
| Example 24 | Resin (24) | A-4 (0.3) | C-2 (0.33) | 2b | W-2 | A1/B1 = 90/10 | 26.5 | 1.00 | 1 | A |
| Comparative | Resin (25) | A-1 (1.4) | C-1 (0.72) | 1b | None | A1/B1 = 90/10 | 23.1 | 0.55 | 1 | C |
| Example 1 | | | | | | | | | | |
| Comparative | Resin (26) | A-2 (1.6) | C-3 (0.72) | 4b | None | A1/A2 = 70/30 | 23.1 | 0.55 | 1 | C |
| Example 2 | | | | | | | | | | |
| Example 25 | Resin (1) | A-1 (1.4) | C-1 (0.72) | 1b | None | A1/B1 = 90/10 | 25.6 | 0.83 | 2 | B |
| Example 26 | Resin (2) | A-2 (1.7) | C-7 (0.49) | 2b | None | A1/B1 = 90/10 | 24.8 | 1.00 | 2 | B |
| Example 27 | Resin (3) | A-7 (1.4) | C-4 (0.45) | 4b | None | A1/A2 = 70/30 | 25.3 | 1.00 | 2 | B |
| Example 28 | Resin (4) | A-5 (1.4) | C-3 (0.40) | 3b | W-1 | A1/B1 = 70/30 | 26.0 | 1.00 | 2 | AA |
| Example 29 | Resin (5) | A-1 (1.9) | C-5 (0.72) | 5b | None | A1/B1 = 70/30 | 26.0 | 1.00 | 2 | AA |
| Example 30 | Resin (6) | A-6 (1.4) | C-2 (0.21) | 1b | None | A1/A3 = 95/5 | 26.5 | 1.00 | 2 | A |
| Example 31 | Resin (7) | A-2 (1.1) | C-6 (0.22) | 4b | None | A1/A2 = 70/30 | 27.6 | 1.00 | 2 | AA |
| Example 32 | Resin (8) | A-8 (2.3) | C-6 (0.32) | 2b | None | A1/B1 = 80/20 | 27.6 | 1.00 | 2 | AA |
| Example 33 | Resin (9) | A-2 (1.5) | C-8 (0.72) | 3b | None | A1/B2 = 90/10 | 25.6 | 0.83 | 2 | B |
| Example 34 | Resin (10) | A-2 (1.6) | C-10 (0.72) | 4b | None | A1/A2 = 70/30 | 26.0 | 1.00 | 2 | AA |
| Example 35 | Resin (11) | A-3 (1.3) | C-2 (0.36) | 5b | W-2 | A1/A2 = 70/30 | 26.5 | 1.00 | 2 | A |
| Example 36 | Resin (12) | A-4 (2.3) | C-8 (0.72) | 5b | None | A1/A2 = 70/30 | 27.6 | 1.00 | 2 | AA |
| Example 37 | Resin (13) | A-3 (1.3) | C-6 (0.72) | 2b | W-1 | A1/A2 = 70/30 | 27.6 | 1.00 | 2 | AA |
| Example 38 | Resin (14) | A-3 (1.3) | C-6 (0.72) | 2b | W-1 | A1/A2 = 70/30 | 26.0 | 1.00 | 2 | AA |
| Example 39 | Resin (15) | A-1 (2.3) | C-2 (0.40) | 2b | W-2 | A1/B2 = 80/20 | 27.6 | 1.00 | 2 | AA |
| Example 40 | Resin (16) | A-10 (1.9) | C-3 (0.45) | 3b | None | A1/B2 = 80/20 | 27.6 | 1.00 | 2 | AA |
| Example 41 | Resin (17) | A-3 (1.3) | C-2 (0.40) | 4b | None | A1/B2 = 80/20 | 26.0 | 1.00 | 2 | AA |
| Example 42 | Resin (18) | A-2 (1.1) | C-6 (0.22) | 4b | None | A1/A2 = 70/30 | 26.0 | 1.00 | 2 | AA |
| Example 43 | Resin (19) | A-2 (0.2)/A-5 (0.7) | C-2 (0.62) | 1b | W-1 | A1/A2 = 70/30 | 27.6 | 1.00 | 2 | AA |
| Example 44 | Resin (20) | A-2 (1.5) | C-2 (1.49) | 4b | W-3 | A1/A2 = 70/30 | 26.5 | 1.00 | 2 | A |
| Example 45 | Resin (21) | A-5 (0.9)/A-11 (0.4) | C-3 (0.77) | 4b | None | A1/B1 = 90/10 | 25.6 | 0.83 | 2 | B |
| Example 46 | Resin (22) | A-4 (0.3) | C-2 (0.33) | 2b | W-2 | A1/B1 = 90/10 | 26.0 | 1.00 | 2 | AA |
| Example 47 | Resin (23) | A-1 (2.3) | C-1 (0.32) | 1b/2b | None | A1/A2 = 70/30 | 27.6 | 1.00 | 2 | AA |
| | | | | (0.02 g/0.03 g) | | | | | | |
| Example 48 | Resin (24) | A-3 (1.3) | C-6 (0.72) | 2b | W-1 | A1/A2 = 70/30 | 26.5 | 1.00 | 2 | A |
| Comparative | Resin (25) | A-1 (1.4) | C-1 (0.72) | 1b | None | A1/B1 = 90/10 | 23.1 | 0.55 | 2 | C |
| Example 3 | | | | | | | | | | |
| Comparative | Resin (26) | A-2 (1.6) | C-3 (0.72) | 4b | None | A1/A2 = 70/30 | 23.1 | 0.55 | 2 | C |
| Example 4 | | | | | | | | | | |

<Resin>

In Table 1, the structures of the resins are as set forth below. Here, Me represents a methyl group, Et represents an ethyl group, and iBu represents an isobutyl group.

In addition, the compositional ratios (the molar ratios; corresponding in order from the left side), the weight-average molecular weight (Mw), and the dispersity (Mw/Mn) of the respective repeating units are shown in Table 2. These were determined by the same method as for the above-mentioned resin (1).

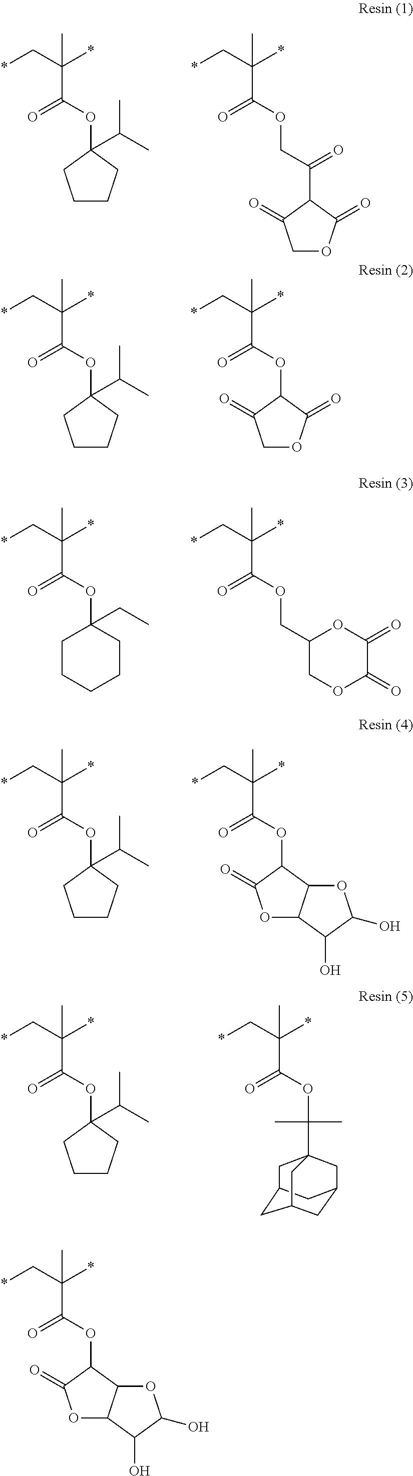

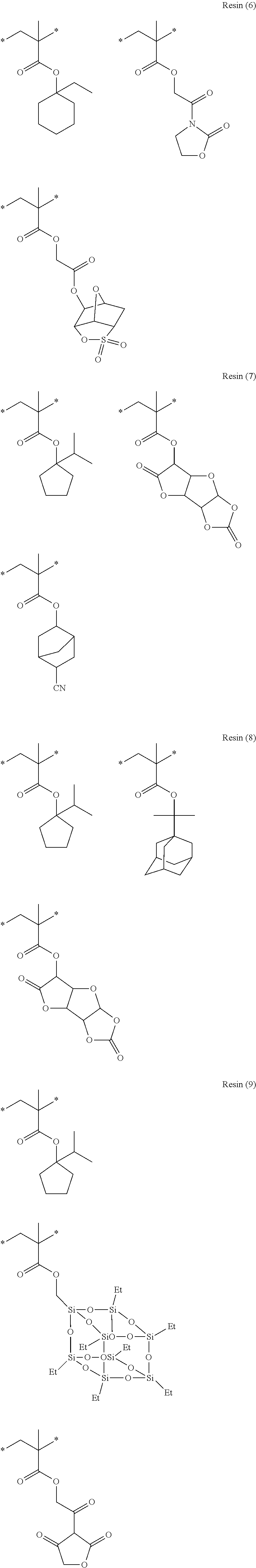

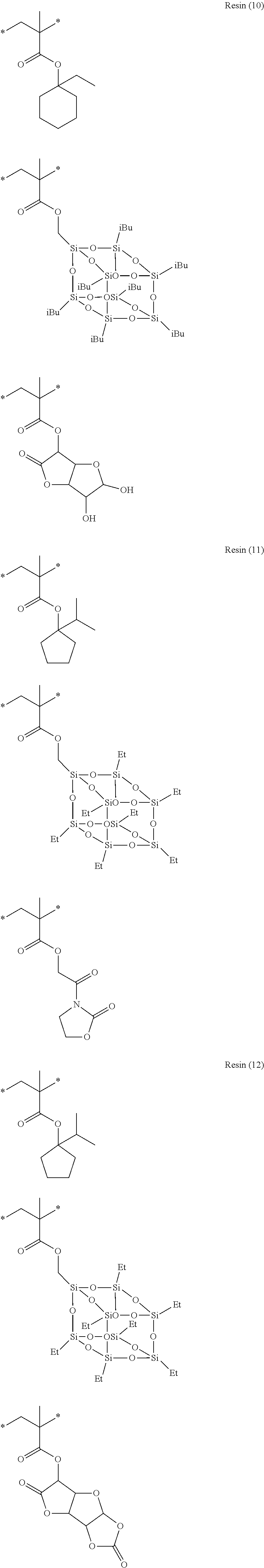

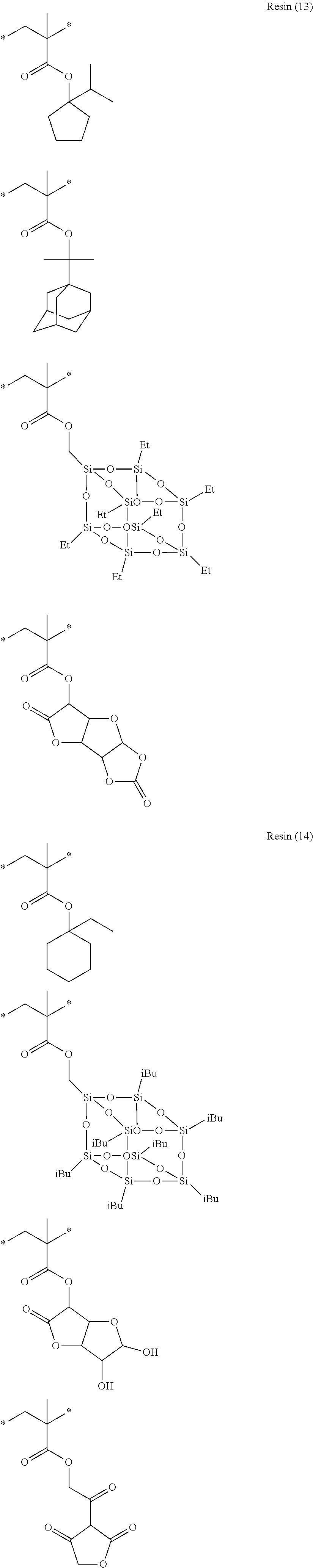

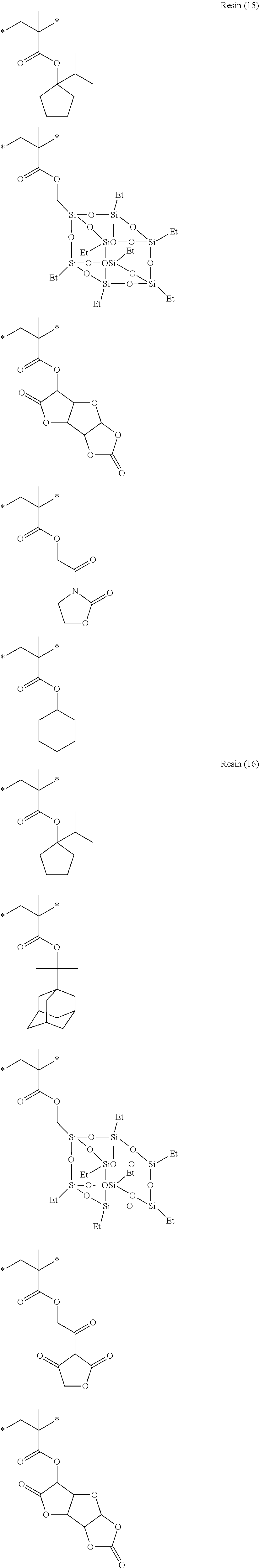

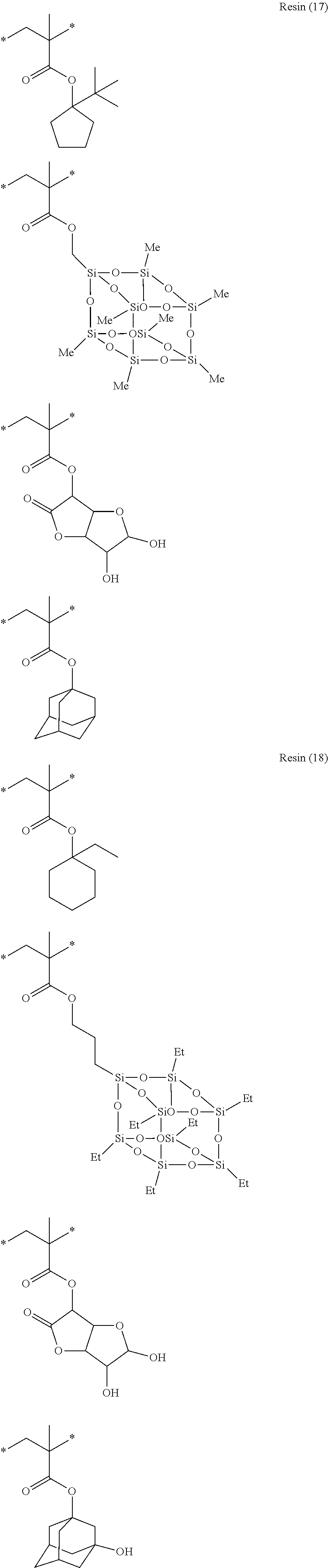

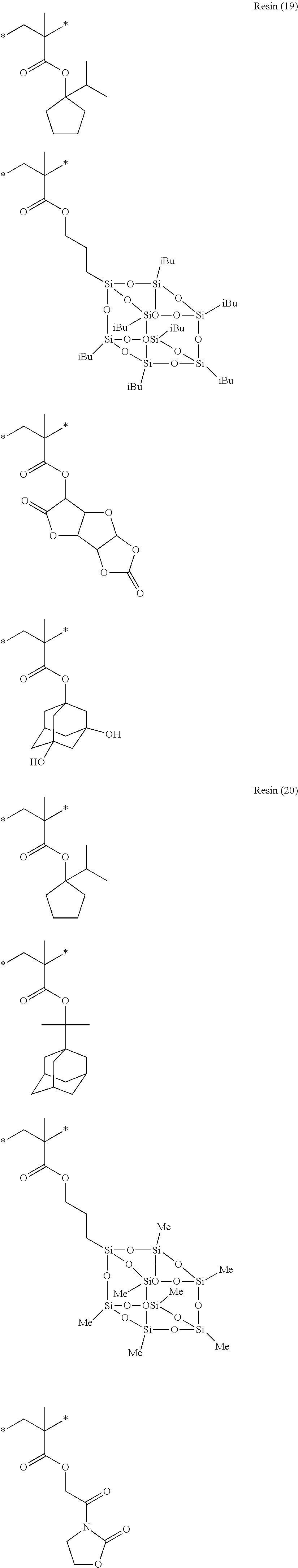

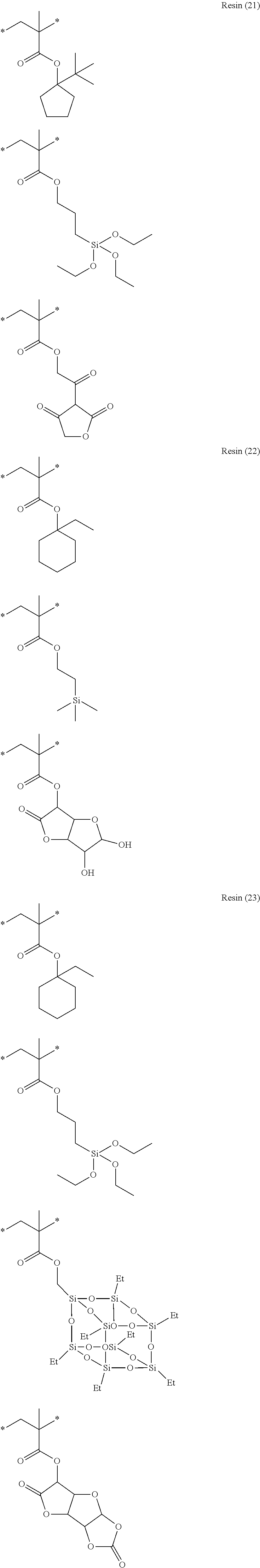

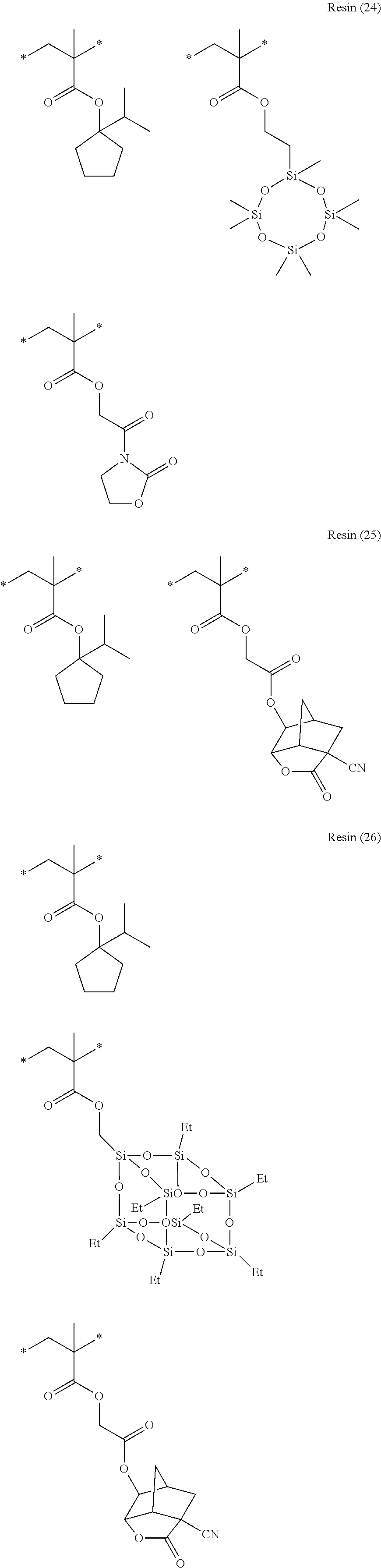

TABLE 2

| | Compositional ratio | | | | | | |
|---|---|---|---|---|---|---|---|
| | (% by mole) | | | | | Mw | Mw/Mn |
| Resin (1) | 70 | 30 | — | — | — | 11,000 | 1.64 |
| Resin (2) | 70 | 30 | — | — | — | 16,000 | 1.69 |
| Resin (3) | 70 | 30 | — | — | — | 10,000 | 1.64 |
| Resin (4) | 75 | 25 | — | — | — | 17,500 | 1.65 |
| Resin (5) | 60 | 10 | 30 | — | — | 11,000 | 1.61 |
| Resin (6) | 70 | 20 | 10 | — | — | 13,500 | 1.68 |
| Resin (7) | 60 | 25 | 15 | — | — | 18,000 | 1.66 |
| Resin (8) | 60 | 10 | 30 | — | — | 18,000 | 1.62 |
| Resin (9) | 63 | 7 | 30 | — | — | 16,000 | 1.6 |
| Resin (10) | 60 | 10 | 30 | — | — | 17,000 | 1.6 |
| Resin (11) | 60 | 12 | 28 | — | — | 17,500 | 1.6 |
| Resin (12) | 60 | 15 | 25 | — | — | 16,500 | 1.61 |
| Resin (13) | 50 | 10 | 10 | 30 | — | 15,500 | 1.61 |
| Resin (14) | 55 | 15 | 20 | 10 | — | 17,000 | 1.62 |
| Resin (15) | 60 | 10 | 10 | 15 | 5 | 18,500 | 1.65 |
| Resin (16) | 45 | 10 | 15 | 15 | 15 | 16,500 | 1.69 |
| Resin (17) | 55 | 10 | 30 | 5 | — | 18,500 | 1.64 |
| Resin (18) | 60 | 8 | 24 | 8 | — | 18,000 | 1.63 |
| Resin (19) | 55 | 10 | 25 | 10 | — | 16,500 | 1.66 |
| Resin (20) | 50 | 10 | 9 | 31 | — | 16,000 | 1.65 |
| Resin (21) | 60 | 20 | 20 | — | — | 15,500 | 1.67 |
| Resin (22) | 50 | 15 | 35 | — | — | 14,000 | 1.69 |
| Resin (23) | 60 | 10 | 10 | 20 | — | 14,500 | 1.7 |
| Resin (24) | 55 | 10 | 35 | — | — | 16,000 | 1.65 |
| Resin (25) | 60 | 40 | — | — | — | 18,000 | 1.62 |
| Resin (26) | 60 | 15 | 25 | — | — | 18,500 | 1.63 |

Furthermore, “the repeating units derived from monomers having at least one of a lactone structure or an amide structure” included in the resins (1) to (26), and the dissolution parameters [(MPa)^{1/2}] of the monomers corresponding to the respective repeating units are set forth below.

Since the monomers corresponding to the four respective repeating units at the top and the monomers corresponding to the first and second repeating units from the left side at the bottom have SP values of 24.0 or more, they correspond to the above-mentioned specific monomers, whereas the monomer corresponding to the first repeating unit from the right side at the bottom has an SP value of less than 24.0, it does not correspond to the above-mentioned specific monomer.

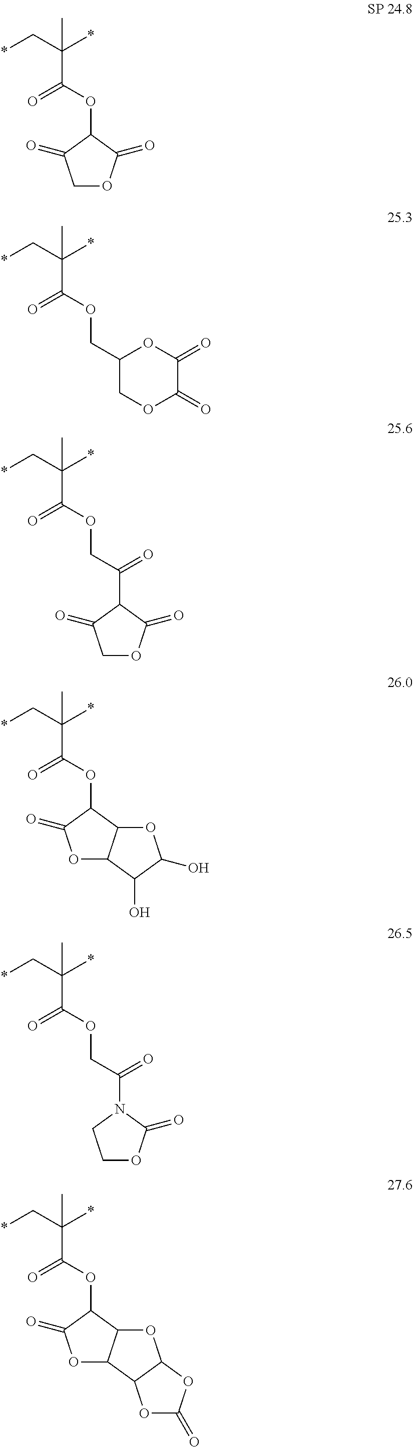

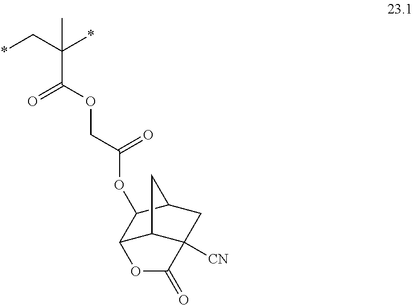

<Acid Generator>

In Table 1, the acid generator is as set forth below. Here, Me represents a methyl group.

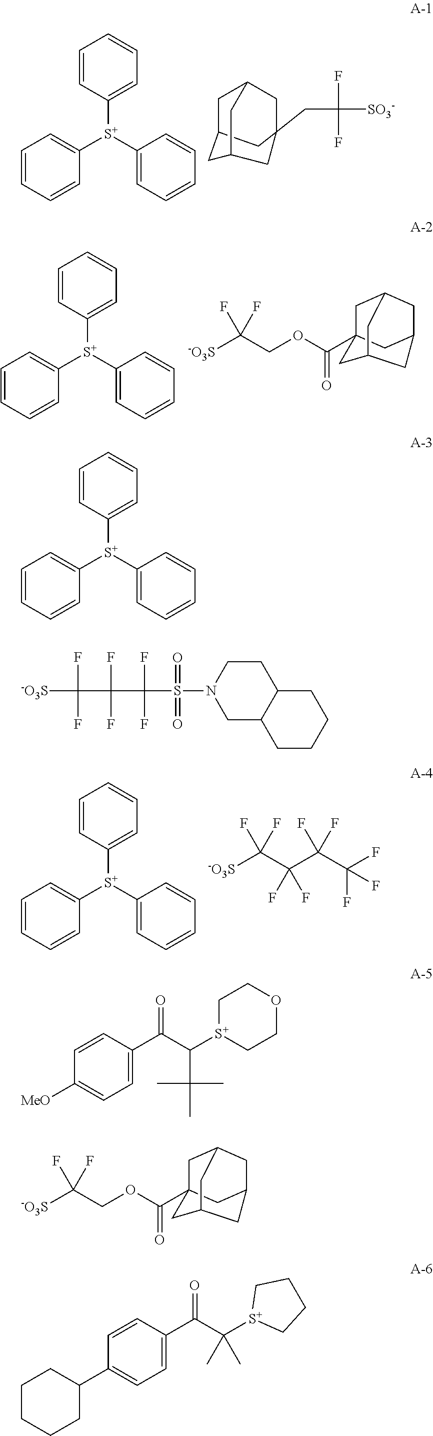

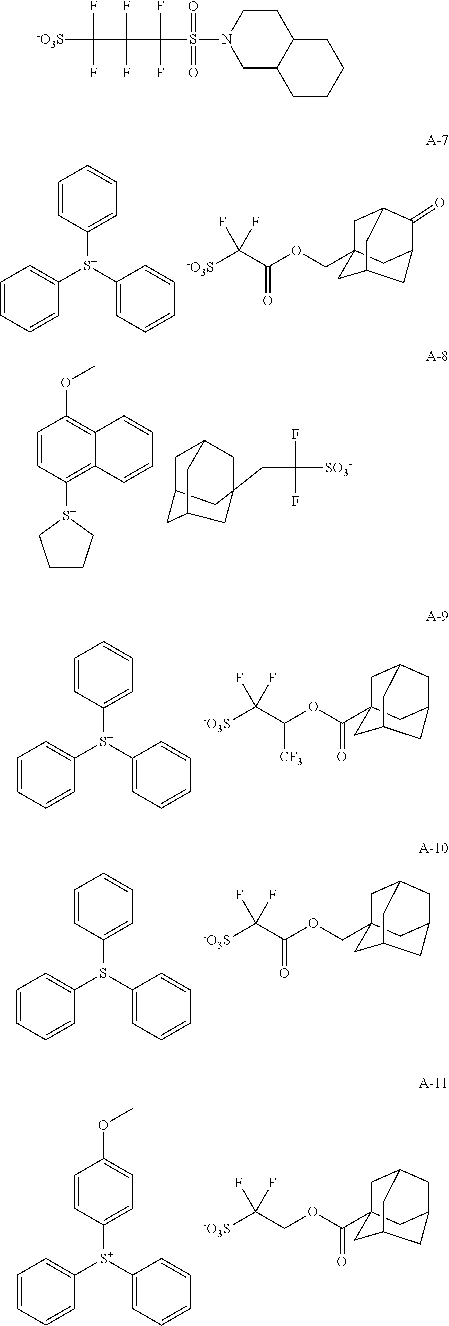

<Acid Diffusion Control Agent>

In Table 1, the acid diffusion control agent is as set forth below.

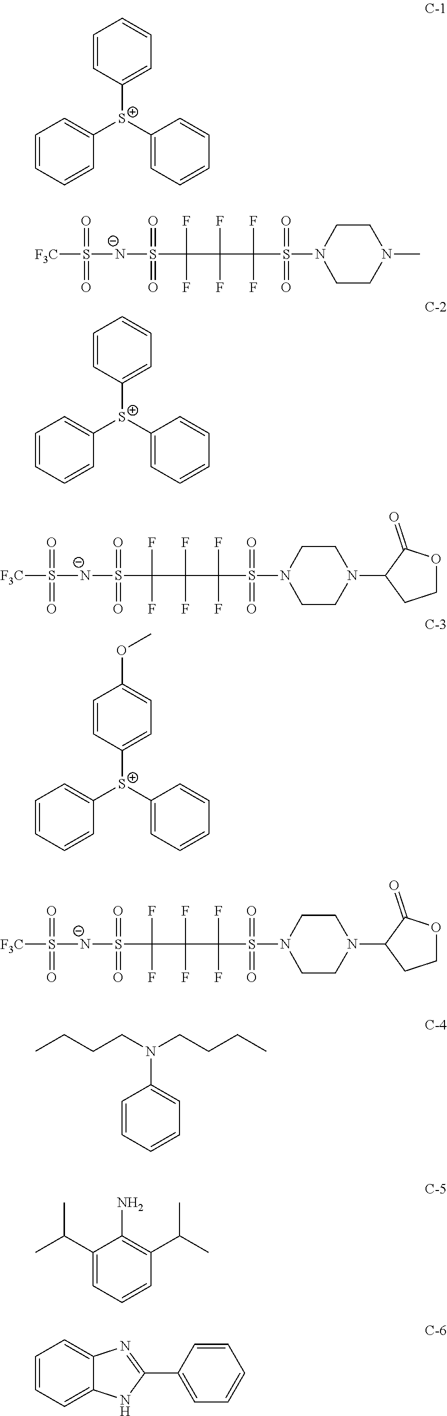

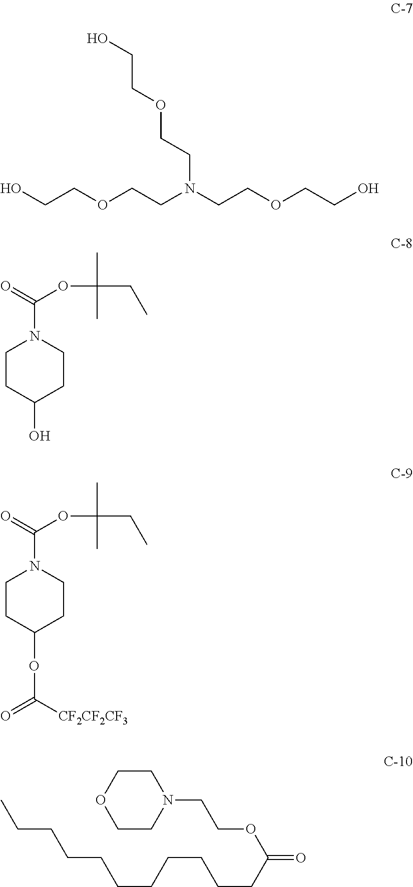

<Hydrophobic Resin>

In Table 1, the hydrophobic resin is as set forth below. Further, the compositional ratios (the molar ratios; corresponding in order from the left side), the weight-average molecular weight (Mw), and the dispersity (Mw/Mn) of the respective repeating units are shown in Table 3. These were determined by the same method as for the above-mentioned resin (1).

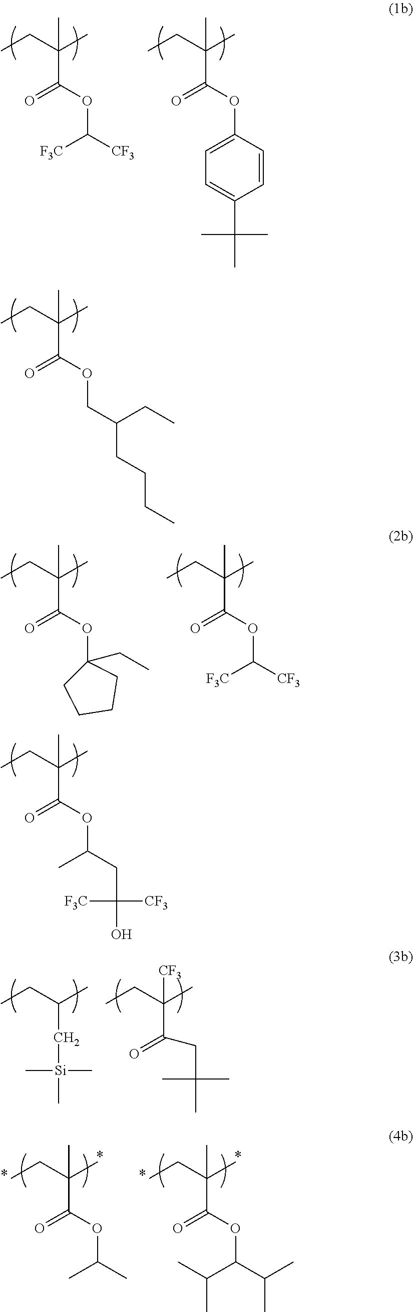

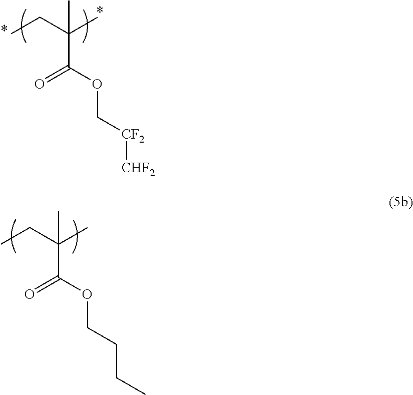

TABLE 3

| | Compositional ratio | | | | |
|---|---|---|---|---|---|
| | (% by mole) | | | Mw | Mw/Mn |
| (1b) | 50 | 45 | 5 | 7,000 | 1.3 |
| (2b) | 40 | 40 | 20 | 18,600 | 1.57 |
| (3b) | 50 | 50 | — | 25,400 | 1.63 |
| (4b) | 30 | 65 | 5 | 28,000 | 1.7 |
| (5b) | 100 | — | — | 12,500 | 1.65 |

<Surfactant>

In Table 1, the surfactant is as set forth below.
W-1: MEGAFACE F176 (manufactured by DIC Corporation) (fluorine-based)
W-2: MEGAFACE R08 (manufactured by DIC Corporation) (fluorine-based and silicon-based)
W-3: PF6320 (manufactured by OMNOVA Solutions Inc.) (fluorine-based)

<Solvent>
A1: Propylene glycol monomethyl ether acetate (PGMEA)
A2: Cyclohexanone
A3: γ-Butyrolactone
B1: Propylene glycol monomethyl ether (PGME)
B2: Ethyl lactate

As shown from Table 1, Examples 1 to 24, and 25 to 48 containing the resins including the repeating units derived from specific monomers exhibited excellent collapse performance. Among those, Examples 4 to 8, 10 to 20, 22 to 24, 28 to 32, 34 to 44, and 46 to 48 in which the SP values of the specific monomers were 26.0 or more exhibited superior collapse performance. Among those, Examples 4 to 5, 7 to 8, 10, 12 to 19, 22, 23, 28 to 29, 31, 32, 34, 36 to 43, 46, and 47 in which the specific monomers are represented by Formula (X), X in Formula (X) is a monovalent group formed by removing any of hydrogen atoms from the compound represented by Formula (X1) or (X2), L₁ and L₂ in Formulae (X1) and (X2) each have two or more substituents, and the substituents are bonded to each other to form a ring exhibited superior collapse performance.

On the other hand, Comparative Examples 1, 2, 3, and 4 in which the resins contained in the compositions did not include the repeating units derived from the specific monomers had insufficient collapse performance.

What is claimed is:

1. An actinic ray-sensitive or radiation-sensitive resin composition comprising a resin whose solubility with respect to a developer changes by the action of an acid,
wherein the resin includes a repeating unit derived from a monomer having at least one of a lactone structure or an amide structure, and
the dissolution parameter of the monomer is 24.0 or more.

2. The actinic ray-sensitive or radiation-sensitive resin composition according to claim 1,
wherein the resin further includes a repeating unit having an Si atom.

3. The actinic ray-sensitive or radiation-sensitive resin composition according to claim 1,
wherein the dissolution parameter of the monomer is 25.0 or more.

4. The actinic ray-sensitive or radiation-sensitive resin composition according to claim 1,
wherein the resin further includes a repeating unit having an acid-decomposable group.

5. An actinic ray-sensitive or radiation-sensitive film formed using the actinic ray-sensitive or radiation-sensitive resin composition according to claim 1.

6. A pattern forming method comprising:
a film forming step of forming an actinic ray-sensitive or radiation-sensitive film on a support, using the actinic ray-sensitive or radiation-sensitive resin composition according to claim 1;
an exposing step of exposing the actinic ray-sensitive or radiation-sensitive film; and
a developing step of developing the exposed actinic ray-sensitive or radiation-sensitive film using a developer.

7. The pattern forming method according to claim 6,
wherein the developer contains an organic solvent.

8. A method for manufacturing an electronic device, comprising the pattern forming method according to claim 6.

9. The actinic ray-sensitive or radiation-sensitive resin composition according to claim 2,
wherein the dissolution parameter of the monomer is 25.0 or more.

10. The actinic ray-sensitive or radiation-sensitive resin composition according to claim 2,
wherein the resin further includes a repeating unit having an acid-decomposable group.

11. The actinic ray-sensitive or radiation-sensitive resin composition according to claim 3,
wherein the resin further includes a repeating unit having an acid-decomposable group.

12. The actinic ray-sensitive or radiation-sensitive resin composition according to claim 9,
wherein the resin further includes a repeating unit having an acid-decomposable group.

13. A pattern forming method comprising:
a film forming step of forming an actinic ray-sensitive or radiation-sensitive film on a support, using the actinic ray-sensitive or radiation-sensitive resin composition according to claim 2;
an exposing step of exposing the actinic ray-sensitive or radiation-sensitive film; and
a developing step of developing the exposed actinic ray-sensitive or radiation-sensitive film using a developer.

14. A pattern forming method comprising:
a film forming step of forming an actinic ray-sensitive or radiation-sensitive film on a support, using the actinic ray-sensitive or radiation-sensitive resin composition according to claim 3;
an exposing step of exposing the actinic ray-sensitive or radiation-sensitive film; and
a developing step of developing the exposed actinic ray-sensitive or radiation-sensitive film using a developer.

15. A pattern forming method comprising:
a film forming step of forming an actinic ray-sensitive or radiation-sensitive film on a support, using the actinic ray-sensitive or radiation-sensitive resin composition according to claim 4;
an exposing step of exposing the actinic ray-sensitive or radiation-sensitive film; and
a developing step of developing the exposed actinic ray-sensitive or radiation-sensitive film using a developer.

16. A pattern forming method comprising:
a film forming step of forming an actinic ray-sensitive or radiation-sensitive film on a support, using the actinic ray-sensitive or radiation-sensitive resin composition according to claim 9;
an exposing step of exposing the actinic ray-sensitive or radiation-sensitive film; and
a developing step of developing the exposed actinic ray-sensitive or radiation-sensitive film using a developer.

17. A pattern forming method comprising:
a film forming step of forming an actinic ray-sensitive or radiation-sensitive film on a support, using the actinic ray-sensitive or radiation-sensitive resin composition according to claim 10;
an exposing step of exposing the actinic ray-sensitive or radiation-sensitive film; and
a developing step of developing the exposed actinic ray-sensitive or radiation-sensitive film using a developer.

18. A pattern forming method comprising:
a film forming step of forming an actinic ray-sensitive or radiation-sensitive film on a support, using the actinic ray-sensitive or radiation-sensitive resin composition according to claim 11;
an exposing step of exposing the actinic ray-sensitive or radiation-sensitive film; and
a developing step of developing the exposed actinic ray-sensitive or radiation-sensitive film using a developer.

19. A pattern forming method comprising:
a film forming step of forming an actinic ray-sensitive or radiation-sensitive film on a support, using the actinic ray-sensitive or radiation-sensitive resin composition according to claim 12;
an exposing step of exposing the actinic ray-sensitive or radiation-sensitive film; and
a developing step of developing the exposed actinic ray-sensitive or radiation-sensitive film using a developer.

20. The pattern forming method according to claim 13,
wherein the developer contains an organic solvent.
